(19) United States
(12) Patent Application Publication
(10) Pub. No.: US 2021/0395461 A1
(43) Pub. Date: Dec. 23, 2021

(54) RESIN COMPOSITION, PHOTOSENSITIVE RESIN COMPOSITION, CURED FILM, METHOD FOR MANUFACTURING CURED FILM, PATTERNED CURED FILM, METHOD FOR PRODUCING PATTERNED CURED FILM

(71) Applicant: CENTRAL GLASS COMPANY, LIMITED, Ube-shi, Yamaguchi (JP)

(72) Inventors: Yutaka SUGITA, Kawagoe-shi, Saitama (JP); Tomohiro KATAMURA, Kawagoe-shi, Saitama (JP); Junya NAKATSUJI, Kawagoe-shi, Saitama (JP); Kazuhiro YAMANAKA, Kawagoe-shi, Saitama (JP); Takashi MASUBUCHI, Kawagoe-shi, Saitama (JP)

(21) Appl. No.: 17/289,471

(22) PCT Filed: Oct. 28, 2019
(86) PCT No.: PCT/JP2019/042183

§ 371 Date: Apr. 28, 2021

(30) Foreign Application Priority Data
Oct. 30, 2018 (JP) 2018-204332

(51) Int. Cl. C08G 77/18; C08J 5/18; G03F 7/075; G03F 7/20; G03F 7/004

(52) U.S. Cl. CPC C08G 77/18; C08J 5/18; G03F 7/0045; G03F 7/20; G03F 7/075

(57) ABSTRACT

Provided is a polysiloxane composition containing a polysiloxane compound including a constitutional unit represented by Formula (1) and at least one of a constitutional unit of Formula (2) and a constitutional unit of Formula (3), and a solvent.

[(R^{x})_{b}R¹ₘSiO_{n/2}] (1)

[(R^{y})_{c}R²ₚSiO_{q/2}] (2)

[SiO_{4/2}] (3)

Here, R^{x} is a monovalent group represented by Formula (1a) (X is a hydrogen atom or an acid-labile group, a is an integer of 1 to 5, and a broken line represents a bond), R^{y} is a monovalent organic group having 1 to 30 carbon atoms, which contains any one of an epoxy group, an oxetane group, an acryloyl group, and a methacryloyl group.

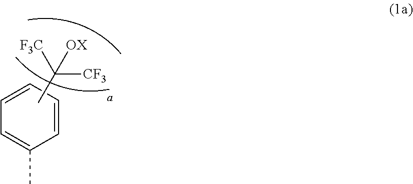

### TECHNICAL FIELD

The present invention relates to a resin composition, a photosensitive resin composition, a cured film, a method for manufacturing a cured film, a patterned cured film, a method for producing a patterned cured film.

### BACKGROUND ART

A high molecular-weight compound containing a siloxane bond (hereinafter, may be referred to as a polysiloxane) is used as a coating material for a liquid crystal display or an organic EL display, a coating material for an image sensor, or a sealing material in the semiconductor field, by utilizing its high heat resistance, high transparency. In addition, it is also used as a hard mask material for a multilayer resist due to having high oxygen plasma resistance. In a case where a polysiloxane is used as a photosensitive material which is capable of being used in pattern formation, the polysiloxane is required to be soluble in an alkaline aqueous solution such as an alkaline developing solution. Examples of the means for solubilizing a polysiloxane in an alkaline developing solution include using a silanol group in a polysiloxane and introducing an acidic group into a polysiloxane. Examples of such an acidic group include a phenol group, a carboxyl group, and a fluorocarbinol group.

For example, Patent Document 1 discloses a polysiloxane in which a silanol group is used as a soluble group in an alkaline developing solution. On the other hand, Patent Document 2 discloses a polysiloxane in which a phenol group is introduced, and Patent Document 3 discloses a polysiloxane in which a carboxyl group is introduced. These polysiloxanes are alkali-soluble resins and are used as a positive type resist composition in combination with a photosensitive compound having a quinone diazide group or in combination with a photoacid generator.

Patent Documents 4 and 5 disclose polysiloxanes in which a fluorocarbinol group which is an acidic group, for example, a hexafluoroisopropanol group (a 2-hydroxy-1,1,1,3,3,3-fluoroisopropyl group [—C(CF₃)₂OH] hereinafter, may be referred to as an HFIP group) is introduced. In a case where the HFIP group-containing polysiloxane is subjected to a heating treatment (curing step), a siloxane bond (Si—O—Si) is promoted to form a cured film having a network structure, and the formed cured film is excellent in transparency, heat resistance, and acid resistance. On the other hand, it is possible to impart alkali solubility (which means solubility in an alkaline aqueous solution) to the polysiloxane before curing, which is indispensable for development treatment. At this point, the polysiloxanes disclosed in Patent Documents 4 and 5 are excellent materials that are well-balanced. In addition, a positive type photosensitive resin composition in which a photoacid generator or a quinone diazide compound is added to the polysiloxane is also disclosed in the above Patent Documents.

In addition, Patent Document 6 describes that, in a case where a polysiloxane is used as a protective film for a liquid crystal display or an organic EL display, from the viewpoint of the resistance to chemical liquids such as an acidic or alkaline resist stripping solution used in the step up to the completion of the display panel and N-methylpyrrolidone (hereinafter, may be referred to as NMP) and environmental harmony in addition to heat resistance and transparency, it is necessary to reduce the amount of benzene generated in the above step and is effective to introduce a naphthalene structure into the polysiloxane structure.

### RELATED DOCUMENT

### Patent Document

[Patent Document 1] Japanese Unexamined Patent Publication No. 2012-242600

[Patent Document 2] Japanese Unexamined Patent Publication No, A-H04-130324

[Patent Document 3] Japanese Unexamined Patent Publication No. 2005-330488

[Patent Document 4] Japanese Unexamined Patent Publication No. 2014-156461

[Patent Document 5] Japanese Unexamined Patent Publication No. 2015-129908

[Patent Document 6] Japanese Unexamined Patent Publication No. 2014-149330

### SUMMARY OF THE INVENTION

### Technical Problem

As described above, since a film obtained by heat-curing the polysiloxane in which an HFIP group is introduced as an acidic group, that is, the polysiloxane each of which is disclosed in Patent Documents 4 and 5, has transparency, heat resistance, and acid resistance. Moreover, the polysiloxane before curing is suitable for development treatment, because it has alkali solubility (solubility for alkali water solution). The polysiloxane is excellent in these points.

However, in the studies by the inventors of the present invention, it has been found that in the film obtained by curing the polysiloxane by the curing step, the chemical liquid resistance to organic solvents such as NMP and propylene glycol monomethyl ether acetate (hereinafter, may be referred to as PGMEA) that is used in the manufacturing step of a liquid crystal display or an organic EL display is still insufficient (see Comparative Examples 1 to 3 described later). At this point, the polysiloxanes in which an HFIP group was introduced, which are disclosed in Patent Document 4 and Patent Document 5, were still had room for improvement.

### Solution to Problem

As a result of diligent studies to solve the above problems, the inventors of the present invention have found a resin composition containing the following component (A) and component (B).

The component (A): a polysiloxane compound containing

a constitutional unit represented by Formula (1) and

at least one of a constitutional unit of Formula (2) and a constitutional unit of Formula (3),

[(R^{x})_{b}R¹ₘSiO_{n/2}] (1)

[in the formula, R^{x} is a monovalent group represented by Formula (1a),

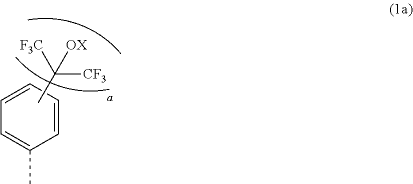

(X is a hydrogen atom or an acid-labile group, a is an integer of 1 to 5, and a broken line represents a bond), R¹ is a hydrogen atom, an alkyl group having 1 to 3 carbon atoms, a phenyl group, a hydroxy group, an alkoxy group having 1 to 3 carbon atoms, or a fluoroalkyl group having 1 to 3 carbon atoms, b is an integer of 1 to 3, m is an integer of 0 to 2, and n is an integer of 1 to 3, where b+m+n is 4, and in a case where a plurality of R^{x}'s and R¹'s are present, R^{x}'s and R¹'s each may be independently the aforementioned group as a substituent],

[(R^{y})_{c}R²ₚSiO_{q/2}] (2)

[in the formula, R^{y} is a monovalent organic group having 1 to 30 carbon atoms, which contains any one of an epoxy group, an oxetane group, an acryloyl group, and a methacryloyl group, R² is a hydrogen atom, an alkyl group having 1 to 3 carbon atoms, a phenyl group, a hydroxy group, an alkoxy group having 1 to 3 carbon atoms, or a fluoroalkyl group having 1 to 3 carbon atoms, c is an integer of 1 to 3, p is an integer of 0 to 2, and q is an integer of 1 to 3, where c+p+q is 4, and in a case where a plurality of R^{y} 's and R²'s are present, R^{y} 's and R²'s each may be independently the aforementioned group as a substituent].

[SiO_{4/2}] (3)

The component (B): a solvent.

It has been found that, similarly to the polysiloxanes disclosed in Patent Documents 4 and 5, the resin composition having such a configuration becomes a cured film by being applied onto a substrate and subjected to a heating treatment (curing step), but the obtained cured film is excellent in heat stability, transparency, and acid resistance (which means resistance to an acidic aqueous solution), while maintaining their levels comparable to (almost the same levels as those of) the polysiloxane compounds disclosed in Patent Documents 4 and 5, and further has the dramatically improved organic solvent resistance (which means resistance to an organic solvent), and thus the resin composition is an excellent material well-balanced overall.

In addition, it has been found that the alkali solubility of the “polysiloxane before the curing treatment” is at the same level as that of the polysiloxanes disclosed in Patent Documents 4 and 5 and may be used in development treatment without problems.

In the present invention, the “polysiloxane compound of the component (A)” includes both the following type a and type b.

<The Type a>

A polysiloxane compound obtained by copolymerizing;

a siloxane monomer that provides a constitutional unit represented by Formula (1) and

at least one of a siloxane monomer that provides a constitutional unit of Formula (2) and a siloxane monomer that provides a structural unit of Formula (3).

<The Type b>

A so-called block copolymer type polysiloxane compound obtained by bonding one polymer to another polymer by forming, for example, a Si—O—Si bond at least one moiety in the molecule to form a high molecular-weight molecule, the one polymer having a certain number of constitutional units represented by Formula (1) which are connected alone therein, and

the other polymer having a certain number of at least constitutional units of Formula (2) or structural units of Formula (3), which are connected alone therein.

Among the polysiloxane compounds of the component (A), the constitutional unit of Formula (1) is the same as the constitutional unit of the polysiloxane compound disclosed in Patent Documents 4 and 5 described above. However, Patent Documents 4 and 5 do not disclose a polysiloxane further containing a constitutional unit represented by Formula (2) or a constitutional unit represented by Formula (3).

As described above, the inventors of the present invention have found that in a case where at least one of a constitutional unit represented by Formula (2) and a constitutional unit represented by Formula (3) is further contained in addition to a constitutional unit represented by Formula (1), it is possible to obtain a polysiloxane composition in which the chemical liquid resistance to an organic solvent is dramatically improved and a cured film of the polysiloxane, as described above.

Further, it has been found that in a case where a photosensitizer such as quinone diazide, a photoacid generator, or a radical generator is contained as a component (C) in the resin composition, the resin composition becomes a resin composition for forming a positive type pattern, and the cured film in which a good positive type pattern is formed can be obtained by performing the first to fourth steps which are described later.

Further, as another aspect of the present invention, the inventors of the present invention have also found a resin composition containing the following component (A1), component (A2), and the component (B) described above.

The component (A1): a polymer containing a constitutional unit represented by Formula (1), but not containing none of a constitutional unit of Formula (2) and a constitutional unit of Formula (3).

The component (A2): a polymer containing at least one of a constitutional unit of Formula (2) and a structural unit of Formula (3), but not containing a constitutional unit represented by Formula (1).

The component (B): a solvent.

In a case where a resin composition having such a configuration (a “resin composition containing the component (A1), the component (A2), and the component (B)”) is adopted, the resin composition at the initial stage is a blend (a mixture) of different kinds of polymers, unlike the “resin composition containing the component (A) and the component (B)” described above.

However, in a case where the “resin composition containing the component (A1), the component (A2), and the component (B)” is applied onto a substrate and heat-treated, a cured film is formed through a curing reaction of an epoxy group, an acryloyl group, or a methacryloyl group and a reaction between silanol groups of different molecules. In this case, after the curing step, “a resin containing the constitutional unit represented by Formula (1), and the constitutional unit of Formula (2) or the constitutional unit of Formula (3)” is generated in the form of a “cured film”. Since such a polymer (a polysiloxane compound) has excellent physical properties, the same merits as those of the “resin composition containing the component (A) and the component (B)” can be also obtained in the present embodiment. The “resin composition containing the component (A1), the component (A2), and the component (B)” also functions as a composition for a positive type resist in a case where the component (C) described above is further added. These will be described in detail by providing a section called “Another embodiment” in the present specification.

The present invention includes the following inventions 1 to 11.

[Invention 1]

A resin composition containing a component (A) and a component (B).

The component (A): a polysiloxane compound containing

a constitutional unit represented by Formula (1) and

at least one of a constitutional unit of Formula (2) and a constitutional unit of Formula (3).

[(R^{x})_{b}R¹ₘSiO_{n/2}] (1)

[in the formula, R^{x} is a monovalent group represented by Formula (1a),

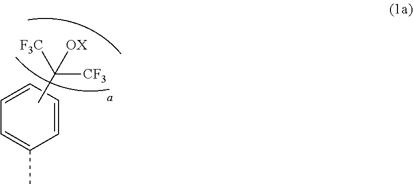

(X is a hydrogen atom or an acid-labile group, a is an integer of 1 to 5, and a broken line represents a bond), R¹ is a hydrogen atom, an alkyl group having 1 to 3 carbon atoms, a phenyl group, a hydroxy group, an alkoxy group having 1 to 3 carbon atoms, or a fluoroalkyl group having 1 to 3 carbon atoms, b is an integer of 1 to 3, m is an integer of 0 to 2, and n is an integer of 1 to 3, where b+m+n is 4, and in a case where a plurality of R^{x}'s and R¹'s are present, R^{x}'s and R¹'s each may be independently the aforementioned group as a substituent],

[(R^{y})_{c}R²ₚSiO_{q/2}] (2)

[in the formula, R^{y} is a monovalent organic group having 1 to 30 carbon atoms, which contains any one of an epoxy group, an oxetane group, an acryloyl group, and a methacryloyl group, R² is a hydrogen atom, an alkyl group having 1 to 3 carbon atoms, a phenyl group, a hydroxy group, an alkoxy group having 1 to 3 carbon atoms, or a fluoroalkyl group having 1 to 3 carbon atoms, c is an integer of 1 to 3, p is an integer of 0 to 2, and q is an integer of 1 to 3, where c+p+q is 4, and in a case where a plurality of R^{y} 's and R²'s are present, R^{y} 's and R²'s each may be independently the aforementioned group as a substituent]

[SiO_{4/2}] (3)

The component (B): a solvent.

[Invention 2]

The resin composition according to Invention 1, in which the group represented by Formula (1a) is any one of groups represented by Formulae (1aa) to (1ad),

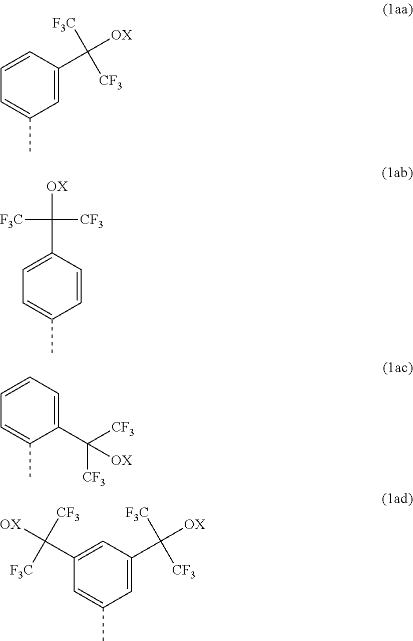

(in the formulae, broken lines represent a bond).

[Invention 3]

The resin composition according to Invention 1 or Invention 2, in which the monovalent organic group R^{y} is a group represented by Formula (2a), (2b), (2c), (3a), or (4a),

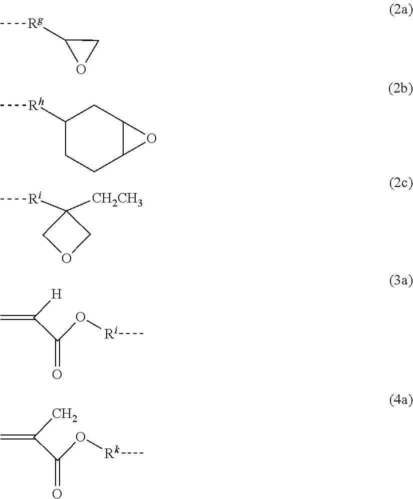

(in the formulae, R^{g}, R^{h}, Rⁱ, R^{j}, and R^{k} each independently represent a linking group or a divalent organic group, and broken lines represent a bond).

[Invention 4]

The resin composition according to any one of Invention 1 to Invention 3, in which the solvent is a solvent containing at least one compound selected from the group consisting of propylene glycol monomethyl ether acetate, propylene glycol monomethyl ether, cyclohexanone, ethyl lactate, γ-butyrolactone, diacetone alcohol, diglyme, methyl isobutyl ketone, 3-methoxybutyl acetate, 2-heptanone, N,N-dimethylformamide, N,N-dimethylacetamide, N-methylpyrrolidone, glycols, glycol ethers, and glycol ether esters.

[Invention 5]

A resin composition containing a component (A1), a component (A2), and a component (B).

The component (A1): a polymer containing a constitutional unit represented by Formula (1), but containing none of a constitutional unit of Formula (2) and a constitutional unit of Formula (3).

The component (A2): a polymer containing at least one of a constitutional unit of Formula (2) and a structural unit of Formula (3), but not containing a constitutional unit represented by Formula (1).

[(R^{x})_{b}R¹ₘSiO_{n/2}] (1)

[in the formula, R^{x} is a monovalent group represented by Formula

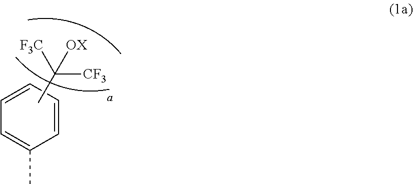

(X is a hydrogen atom or an acid-labile group, a is an integer of 1 to 5, and a broken line represents a bond), R¹ is a hydrogen atom, an alkyl group having 1 to 3 carbon atoms, a phenyl group, a hydroxy group, an alkoxy group having 1 to 3 carbon atoms, or a fluoroalkyl group having 1 to 3 carbon atoms, b is an integer of 1 to 3, m is an integer of 0 to 2, and n is an integer of 1 to 3, where b+m+n is 4, and in a case where a plurality of R^{x}'s and R¹'s are present, R^{x}'s and R¹'s each may be independently the aforementioned group as a substituent],

[(R^{y})_{c}R²ₚSiO_{q/2}] (2)

[in the formula, R^{y} is a monovalent organic group having 1 to 30 carbon atoms, which contains any one of an epoxy group, an oxetane group, an acryloyl group, and a methacryloyl group, R² is a hydrogen atom, an alkyl group having 1 to 3 carbon atoms, a phenyl group, a hydroxy group, an alkoxy group having 1 to 3 carbon atoms, or a fluoroalkyl group having 1 to 3 carbon atoms, c is an integer of 1 to 3, p is an integer of 0 to 2, and q is an integer of 1 to 3, where c+p+q is 4, and in a case where a plurality of R^{y} 's and R²'s are present, R^{y} 's and R²'s each may be independently the aforementioned group as a substituent]

[SiO_{4/2}] (3)

The component (B): a solvent.

[Invention 6]

A photosensitive resin composition containing:

the resin composition according to any one of Inventions 1 to 5 and a photosensitizer as a component (C), which is selected from a quinone diazide compound, a photoacid generator, and photoradical generator.

[Invention 7]

A cured film of the resin composition according to any one of Inventions 1 to 5.

[Invention 8]

A method for manufacturing a cured film, including applying the resin composition according to any one of Inventions 1 to 5 onto a substrate and then performing heating at a temperature of 100° C. to 350° C.

[Invention 9]

A patterned cured film of the photosensitive resin composition according to Invention 6.

[Invention 10]

A method for manufacturing a patterned cured film, including the following first to fourth steps:

the first step: a step of applying the photosensitive resin composition according to Invention 6 onto a substrate and performing drying to form a photosensitive resin film,

the second step: a step of exposing the photosensitive resin film,

the third step: a step of developing the exposed photosensitive resin film to form a patterned resin film, and

the fourth step: a step of heating the patterned resin film, thereby curing the patterned resin film such that the patterned resin film is converted into a patterned cured film.

[Invention 11]

The method for manufacturing the patterned cured film according to Invention 10, in which a wavelength of light that is used for the exposure in the second step is 100 to 600 nm.

[Invention 12]

A method for producing the resin composition according to any one of Inventions 1 to 4, including:

converting a hydrogen atom of a hydroxy group of an alkoxysilane represented by Formula (7) or Formula (7-1) into an acid-labile group to obtain an acid labile group-containing alkoxysilane, subsequently hydrolyzing and polycondensing the acid labile group-containing alkoxysilane to obtain a polysiloxane compound, and using the obtained polysiloxane compound as the polysiloxane compound of the component (A) in a case of producing the resin composition,

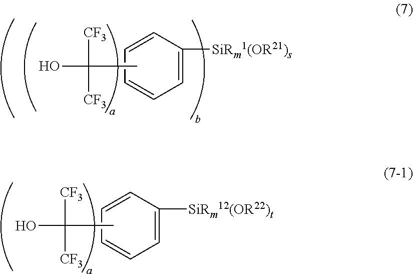

[in Formula (7), R¹'s are each independently a hydrogen atom, an alkyl group having 1 to 3 carbon atoms, a phenyl group, a hydroxy group, an alkoxy group having 1 to 3 carbon atoms, or a fluoroalkyl group having 1 to 3 carbon atoms, R²¹'s are each independently a linear alkyl group having 1 to 4 carbon atoms or a branched alkyl group having 3 or 4 carbon atoms, all or a part of hydrogen atoms in the alkyl group may be substituted with fluorine atoms, a is an integer of 1 to 5, b is an integer of 1 to 3, m is an integer of 0 to 2, and s is an integer of 1 to 3, where b+m+s is 4, and

in Formula (7-1), R¹²'s are each independently a hydrogen atom, an alkyl group having 1 to 3 carbon atoms, a phenyl group, a hydroxy group, an alkoxy group having 1 to 3 carbon atoms, or a fluoroalkyl group having 1 to 3 carbon atoms, R²²'s are each independently a linear alkyl group having 1 to 4 carbon atoms or a branched alkyl group having 3 or 4 carbon atoms, all or a part of hydrogen atoms in the alkyl group may be substituted with fluorine atoms, a is an integer of 1 to 5, m is an integer of 0 to 2, and r is an integer of 1 to 3, where m+r is 3].

[Invention 13]

A method for producing the resin composition according to any one of Inventions 1 to 4, including:

hydrolyzing and polycondensing an alkoxysilane represented by Formula (7) or Formula (7-1) to obtain a polymer, subsequently converting a hydrogen atom of a hydroxy group of the polymer into an acid-labile group to obtain a polysiloxane compound, and using the obtained polysiloxane compound as the polysiloxane compound of the component (A) in a case of producing the resin composition,

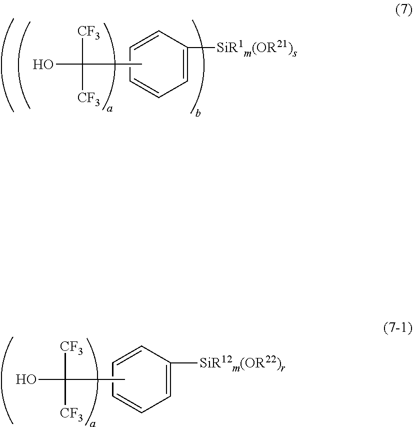

[in Formula (7), R¹'s are each independently a hydrogen atom, an alkyl group having 1 to 3 carbon atoms, a phenyl group, a hydroxy group, an alkoxy group having 1 to 3 carbon atoms, or a fluoroalkyl group having 1 to 3 carbon atoms, R²¹'s are each independently a linear alkyl group having 1 to 4 carbon atoms or a branched alkyl group having 3 or 4 carbon atoms, all or a part of hydrogen atoms in the alkyl group may be substituted with fluorine atoms, a is an integer of 1 to 5, b is an integer of 1 to 3, m is an integer of 0 to 2, and s is an integer of 1 to 3, where b+m+s is 4, and

in Formula (7-1), R¹²'s are each independently a hydrogen atom, an alkyl group having 1 to 3 carbon atoms, a phenyl group, a hydroxy group, an alkoxy group having 1 to 3 carbon atoms, or a fluoroalkyl group having 1 to 3 carbon atoms, R²²'s are each independently a linear alkyl group having 1 to 4 carbon atoms or a branched alkyl group having 3 or 4 carbon atoms, all or a part of hydrogen atoms in the alkyl group may be substituted with fluorine atoms, a is an integer of 1 to 5, m is an integer of 0 to 2, and r is an integer of 1 to 3, where m+r is 3].

[Invention 14]

A method for producing the resin composition according to Invention 5, including:

converting a hydrogen atom of a hydroxy group of an alkoxysilane represented by Formula (7) or Formula (7-1) into an acid-labile group to obtain an acid labile group-containing alkoxysilane, subsequently hydrolyzing and polycondensing the acid labile group-containing alkoxysilane to obtain a polymer, and using the obtained polymer as the polymer of the component (A1) in a case of producing the resin composition,

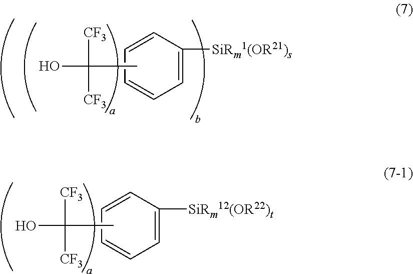

[in Formula (7), R¹'s are each independently a hydrogen atom, an alkyl group having 1 to 3 carbon atoms, a phenyl group, a hydroxy group, an alkoxy group having 1 to 3 carbon atoms, or a fluoroalkyl group having 1 to 3 carbon atoms, R²¹'s are each independently a linear alkyl group having 1 to 4 carbon atoms or a branched alkyl group having 3 or 4 carbon atoms, all or a part of hydrogen atoms in the alkyl group may be substituted with fluorine atoms, a is an integer of 1 to 5, b is an integer of 1 to 3, m is an integer of 0 to 2, and s is an integer of 1 to 3, where b+m+s is 4, and

in Formula (7-1), R¹²'s are each independently a hydrogen atom, an alkyl group having 1 to 3 carbon atoms, a phenyl group, a hydroxy group, an alkoxy group having 1 to 3 carbon atoms, or a fluoroalkyl group having 1 to 3 carbon atoms, R²²'s are each independently a linear alkyl group having 1 to 4 carbon atoms or a branched alkyl group having 3 or 4 carbon atoms, all or a part of hydrogen atoms in the alkyl group may be substituted with fluorine atoms, a is an integer of 1 to 5, m is an integer of 0 to 2, and r is an integer of 1 to 3, where m+r is 3].

[Invention 15]

A method for producing the resin composition according to claim 5, including:

hydrolyzing and polycondensing an alkoxysilane represented by Formula (7) or Formula (7-1) to obtain a polymer, subsequently converting a hydrogen atom of a hydroxy group of the polymer into an acid-labile group to obtain a polymer, and using the obtained polymer as the polymer of the component (A1) in a case of producing the resin composition,

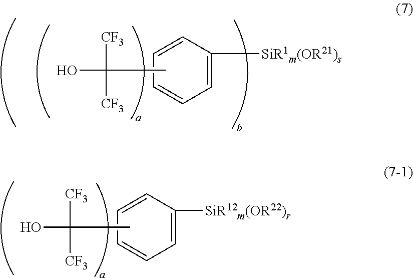

[in Formula (7), R¹'s are each independently a hydrogen atom, an alkyl group having 1 to 3 carbon atoms, a phenyl group, a hydroxy group, an alkoxy group having 1 to 3 carbon atoms, or a fluoroalkyl group having 1 to 3 carbon atoms, R²¹'s are each independently a linear alkyl group having 1 to 4 carbon atoms or a branched alkyl group having 3 or 4 carbon atoms, all or a part of hydrogen atoms in the alkyl group may be substituted with fluorine atoms, a is an integer of 1 to 5, b is an integer of 1 to 3, m is an integer of 0 to 2, and s is an integer of 1 to 3, where b+m+s is 4, and

in Formula (7-1), R¹²'s are each independently a hydrogen atom, an alkyl group having 1 to 3 carbon atoms, a phenyl group, a hydroxy group, an alkoxy group having 1 to 3 carbon atoms, or a fluoroalkyl group having 1 to 3 carbon atoms, R²²'s are each independently a linear alkyl group having 1 to 4 carbon atoms or a branched alkyl group having 3 or 4 carbon atoms, all or a part of hydrogen atoms in the alkyl group may be substituted with fluorine atoms, a is an integer of 1 to 5, m is an integer of 0 to 2, and r is an integer of 1 to 3, where m+r is 3].

### Advantageous Effects of Invention

The resin composition of the present invention becomes a cured film by being applied onto a substrate and subjected to a heating treatment (curing step) and have effects that the obtained cured film is excellent in heat stability, transparency, and acid resistance (which means resistance to an acidic aqueous solution) and the organic solvent resistance (which means resistance to an organic solvent) is significantly improved as compared with the polysiloxane resin compositions disclosed in Patent Documents 4 and 5.

In addition, in a case where a photosensitizer such as quinone diazide, a photoacid generator, or a radical generator is contained as a component (C) in the resin composition, the resin composition becomes a resin composition for forming a positive type pattern and have effects that a cured film in which a good positive type pattern is formed can be obtained.

### DESCRIPTION OF EMBODIMENTS

Hereinafter, the embodiments of the present invention will be described in the following order.

<1> A resin composition containing a component (A) and a component (B)

<2> A photosensitive resin composition further containing a component (C)

<3> Method for manufacturing a cured film of a resin composition

<4> Patterning method using a photosensitive resin composition

<5> Another embodiment: a resin composition containing the component (A1), the component (A2), and the component (B)

<6> Method for synthesizing a raw material compound of a constitutional unit of Formula (1)

Hereinafter, in the present specification, a broken line in the chemical formula represents a bond.

<1> A Resin Composition Containing a Component (A) and a Component (B)

The resin composition contains the following component (A) and component (B).

The component (A): a polysiloxane compound containing

a constitutional unit represented by Formula (1) and

at least one of a constitutional unit of Formula (2) and a constitutional unit of Formula (3),

[(R^{x})_{b}R¹ₘSiO_{n/2}] (1)

[in the formula, R^{x} is a monovalent group represented by Formula (1a),

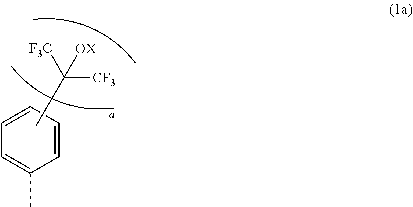

(X is a hydrogen atom or an acid-labile group, a is an integer of 1 to 5, and a broken line represents a bond), R¹ is a hydrogen atom, an alkyl group having 1 to 3 carbon atoms, a phenyl group, a hydroxy group, an alkoxy group having 1 to 3 carbon atoms, or a fluoroalkyl group having 1 to 3 carbon atoms, b is an integer of 1 to 3, m is an integer of 0 to 2, and n is an integer of 1 to 3, where b+m+n=4, and in a case where a plurality of R^{x}'s and R¹'s are present, R^{x}'s and R¹'s each may be independently the aforementioned group as a substituent],

[(R^{y})_{c}R²ₚSiO_{q/2}] (2)

[in the formula, R^{y} is a monovalent organic group having 1 to 30 carbon atoms, which contains any one of an epoxy group, an oxetane group, an acryloyl group, and a methacryloyl group, R² is a hydrogen atom, an alkyl group having 1 to 3 carbon atoms, a phenyl group, a hydroxy group, an alkoxy group having 1 to 3 carbon atoms, or a fluoroalkyl group having 1 to 3 carbon atoms, c is an integer of 1 to 3, p is an integer of 0 to 2, and q is an integer of 1 to 3, where c+p+q is 4, and in a case where a plurality of R^{y} 's and R²'s are present, R^{y} 's and R²'s each may be independently the aforementioned group as a substituent]

[SiO_{4/2}] (3)

The component (B): a solvent.

In the polysiloxane compound containing the constitutional unit represented by Formula (1), an HFIP group or a hydroxyl group of an HFIP group or is chemically modified with an acid-labile group. As described above, in a case where an HFIP group is introduced into the polysiloxane compound, solubility in an alkaline developing solution can be exhibited. Further, the HFIP group is a polar group containing a fluorine atom and a hydroxyl group and has excellent solubility in a coating solvent for general use. In a case where the hydroxyl group of the HFIP group is chemically modified with the acid-labile group, the solubility in an organic solvent can be adjusted, and as will be described in detail later, patterning performance using a photoacid generator can be imparted.

O_{n/2} in Formula (1) is generally used as a notation for a polysiloxane compound. Formula (1-1) is for representing a case where n is 1, Formula (1-2) is for representing a case where n is 2, Formula (1-3) is for representing a case where n is 3. In a case where n is 1, it is located at the terminal of the polysiloxane chain in the polysiloxane compound.

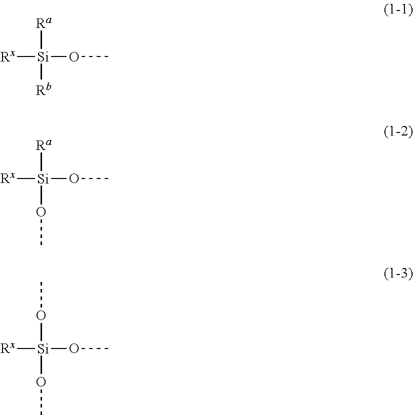

(In the formulae, R^{x} has the same meaning as R^{x} in Formula (1), R^{a} and R^{b} are independently the same as R^{x} and R¹ in Formula (1), respectively. Broken lines represent a bond).

Regarding the notation of O_{n/2} in Formula (2), Formula (2-1) is for representing a case where n is 1, Formula (2-2) is for representing a case where n is 2, Formula (2-3) is for representing a case where n is 3, as similarly described above. In a case where n is 1, it is located at the terminal of the polysiloxane chain in the polysiloxane compound.

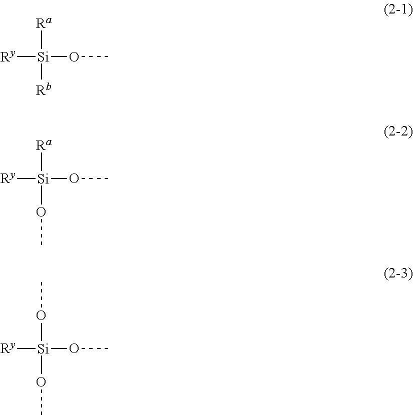

(In the formulae, R^{y} has the same meaning as R^{y} in Formula (2), R^{a} and R^{b} are independently the same as R^{y} and R² in Formula (2), respectively. Broken lines represent a bond).

The case of O_{4/2} in Formula (3) indicates a polysiloxane compound represented by Formula (3-1).

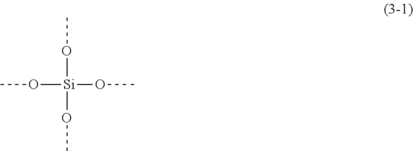

(In the formula, broken lines represent a bond).

Hereinafter, the constitutional units of the component (A), which are represented by Formulae (1), (2), and (3) will be described in order.

[Constitutional unit represented by Formula (1)]

[(R^{x})_{b}R¹ₘSiO_{n/2}] (1)

[in the formula, R^{x} is a monovalent group represented by Formula (1a)

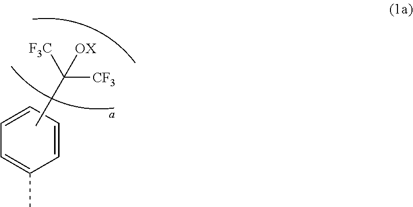

(X is a hydrogen atom or an acid-labile group, a is an integer of 1 to 5, and a broken line represents a bond), R¹ is a hydrogen atom, an alkyl group having 1 to 3 carbon atoms, a phenyl group, a hydroxy group, an alkoxy group having 1 to 3 carbon atoms, or a fluoroalkyl group having 1 to 3 carbon atoms, b is an integer of 1 to 3, m is an integer of 0 to 2, and n is an integer of 1 to 3, where b+m+n=4, and in a case where a plurality of R^{x}'s and R¹'s are present, R^{x}'s and R¹'s each may be independently the aforementioned group as a substituent.]

In Formula (1), specific examples of R¹ include a hydrogen atom, a methyl group, an ethyl group, a 3,3,3-trifluoropropyl group, and a phenyl group. b is preferably 1 or 2. m is preferably 0 or 1. n is preferably 2 or 3. a is preferably 1 or 2.

Among the above, from the viewpoint of easiness of production, the constitutional unit of Formula (1) is particularly preferably a constitutional unit having one HFIP group-containing aryl group represented by Formula (1a) in Formula (1), that is, a constitutional unit in which b is 1.

Next, the acid-labile group will be described. The acid-labile group is the so-called group that is eliminated by the action of an acid and may contain an oxygen atom, a carbonyl bond, or a fluorine atom as a part thereof.

As the acid-labile group, any group that is eliminated due to the effect of a photoacid generator or hydrolysis can be used without particular limitation, and specific examples thereof include an alkyl group, an alkyloxycarbonyl group, an acetal group, a silyl group, and an acyl group.

Examples of the alkyl group include a tert-butyl group, a tert-amyl group, a 1,1-dimethylpropyl group, a 1-ethyl-1-methylpropyl group, a 1,1-dimethylbutyl group, an allyl group, a 1-pyrenylmethyl group, a 5-dibenzosveryl group, a triphenylmethyl group, a 1-ethyl-1-methylbutyl group, a 1,1-diethylpropyl group, a 1,1-dimethyl-1-phenylmethyl group, a 1-methyl-1-ethyl-1-phenylmethyl group, a 1,1-diethyl-1-phenylmethyl group, a 1-methylcyclohexyl group, a 1-ethylcyclohexyl group, a 1-methylcyclopentyl group, a 1-ethylcyclopentyl group, a 1-isobornyl group, a 1-methyladamantyl group, a 1-ethyl adamantyl group, a 1-isopropyladamantyl group, a 1-isopropylnorbornyl group, and a 1-isopropyl-(4-methylcyclohexyl) group. The alkyl group is preferably a tertiary alkyl group, more preferably a group represented by —CR^{p}R^{q}R^{r} (R^{p}, R^{q}, and R^{r} are each independently a linear or branched alkyl group, a monocyclic or polycyclic cycloalkyl group, an aryl group, or an aralkyl group, and two of R^{p}, R^{q}, and R^{r} may be bonded to form a ring structure).

Examples of the alkoxycarbonyl group include a tert-butoxycarbonyl group, a tert-amyloxycarbonyl group, a methoxycarbonyl group, an ethoxycarbonyl group, and an i-propoxycarbonyl group. Examples of the acetal groups include a methoxymethyl group, an ethoxyethyl group, a butoxyethyl group, a cyclohexyloxyethyl group, a benzyloxyethyl group, a phenethyloxyethyl group, an ethoxypropyl group, a benzyloxypropyl group, a phenethyloxypropyl group, an ethoxybutyl group, and an ethoxyisobutyl group.

Examples of the silyl group include a trimethylsilyl group, an ethyldimethylsilyl group, a methyldiethylsilyl group, a triethylsilyl group, an i-propyldimethylsilyl group, a methyldi-i-propylsilyl group, a tri-i-propylsilyl group, and a t-butyldimethylsilyl group, a methyldi-t-butylsilyl group, a tri-t-butylsilyl group, a phenyldimethylsilyl group, a methyldiphenylsilyl group, and a triphenylsilyl group.

Examples of the acyl group include, an acetyl group, a propionyl group, a butyryl group, a heptanoyl group, a hexanoyl group, a valeryl group, a pivaloyl group, an isovaleryl group, a laurylloyl group, a myritoyl group, a palmitoyl group, a stearoyl group, an oxalyl group, a malonyl group, a succinyl group, a glutalyl group, an adipoil group, a piperoyl group, a suberoyl group, an azelaoyl group, a sebacoil group, an acryloyl group, a propioloyl group, a methacryloyl group, a crotonoyle group, an oleoyl group, a maleoyl group, a fumaroyl group, a mesaconoyl group, a camphoroyl group, a benzoyl group, a phthaloyl group, an isophthaloyl group, a terephthaloyl group, a naphthoyl group, a toluoyl group, a hydroatropoyl group, an atropoyl group, a cinnamoyl group, a floyl group, a tenoyl group, a nicotinoyl group, an isonicotinoyl group.

Among them, a tert-butoxycarbonyl group, a methoxymethyl group, an ethoxyethyl group, and a trimethylsilyl group are for general purpose and preferable. Further, groups in which a part or all of the hydrogen atoms of these acid-labile groups are substituted with fluorine atoms can also be used. A single kind of these acid-labile groups may be used, or a plurality of kinds thereof may be used.

The particularly preferred structures of the acid-labile group include a structure represented by Formula (ALG-1) and a structure represented by Formula (ALG-2).

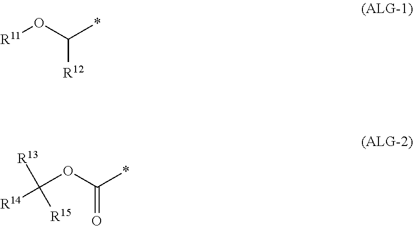

[In the formula, R¹¹ is a linear alkyl group having 1 to 10 carbon atoms, a branched alkyl group having 3 to 10 carbon atoms, or a cyclic alkyl group having 3 to 10 carbon atoms, an aryl group having 6 to 20 carbon atoms, or an aralkyl group having 7 to 21 carbon atoms. R¹² is a hydrogen atom, a linear alkyl group having 1 to 10 carbon atoms, a branched alkyl group having 3 to 10 carbon atoms, or a cyclic alkyl group having 3 to 10 carbon atoms, an aryl group having 6 to 20 carbon atoms, or an aralkyl group having 7 to 21 carbon atoms. R¹³, R¹⁴, and R¹⁵ are each independently a linear alkyl group having 1 to 10 carbon atoms, a branched alkyl group having 3 to 10 carbon atoms, or a cyclic alkyl group having 3 to 10 carbon atoms, an aryl group having 6 to 20 carbon atoms, or an aralkyl group having 7 to 21 carbon atoms. Two of R¹³, R¹⁴, and R¹⁵ may be bonded to each other to forma ring structure. * Represents a binding position to an oxygen atom.]

The group represented by Formula (1a) in Formula (1) is particularly preferably any one of groups represented by Formulae (1aa) to (1ad).

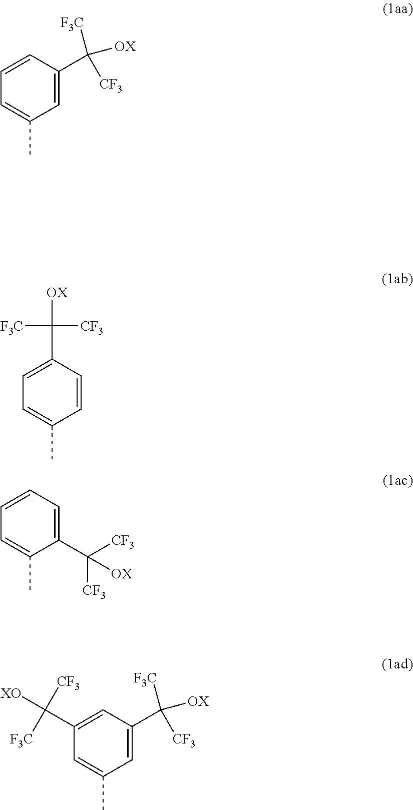

(X is a hydrogen atom or an acid-labile group. Broken lines represent a bond).

[Constitutional unit represented by Formula (2)]

[(R^{y})_{c}R²ₚSiO_{q/2}] (2)

[in the formula, R^{y} is a monovalent organic group having 1 to 30 carbon atoms, which contains any one of an epoxy group, an oxetane group, an acryloyl group, and a methacryloyl group, R² is a hydrogen atom, an alkyl group having 1 to 3 carbon atoms, a phenyl group, a hydroxy group, an alkoxy group having 1 to 3 carbon atoms, or a fluoroalkyl group having 1 to 3 carbon atoms, c is an integer of 1 to 3, p is an integer of 0 to 2, and q is an integer of 1 to 3, where c+p+q is 4, and in a case where a plurality of R^{y}'s and R²'s are present, R^{y}'s and R²'s each may be independently the aforementioned group as a substituent].

In Formula (2), p is preferably 0 or 1. q is preferably 2 or 3. In addition, from the viewpoint of availability, the value of c is particularly preferably 1. Among the above, a particularly preferred example of the constitutional unit of Formula (2) is a constitutional unit in which c is 1, p is 0, and q is 3. Specific examples of R² include a hydrogen atom, a methyl group, an ethyl group, a phenyl group, a methoxy group, an ethoxy group, and a propoxy group.

In a case where a R^{y} group of the constitutional unit represented by Formula (2) contains an epoxy group or an oxetane group, it is possible to impart good adhesion, to a cured film obtained from the resin composition, with various substrates such as silicon, glass, and resin. In a case where the R^{y} group contains an acryloyl group or a methacryloyl group, a cured film having high curability can be obtained, and good solvent resistance can be obtained.

In a case where the R^{y} group contains an epoxy group and an oxetane group, the R^{y} group is preferably a group represented by Formula (2a), (2b), or (2c).

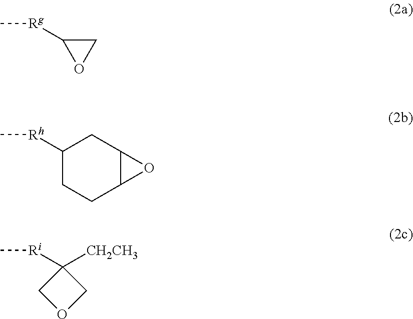

(In the formulae, R^{g}, R^{h}, and Rⁱ each independently represent a linking group or a divalent organic group. Broken lines represent a bond).

Here, in a case where R^{g}, R^{h}, and Rⁱ are a divalent organic group, examples of the divalent organic group include an alkylene group having 1 to 20 carbon atoms, and the divalent organic group may contain one or more moieties in which an ether bond is formed. In a case where the number of carbon atoms is 3 or more, the alkylene group may be branched, or carbons spaced apart from each other may be connected to each other to form a ring. In a case where two or more alkylene groups are present, one or more moieties in which an ether bond is formed by inserting oxygen between carbons may be contained, which are a preferred example as the divalent organic group.

Examples of the alkoxysilane as a raw material for the particularly preferred one among the repeating units of Formula (2) include 3-glycidoxypropyltrimethoxysilane (manufactured by Shin-Etsu Chemical Co., Ltd., product name: KBM-403), 3-glysidoxypropyltriethoxysilane (same as above, product name: KBE-403), 3-glycidoxypropylmethyldiethoxysilane (same as above, product name: KBE-402), 3-glycidoxypropylmethyldimethoxysilane (same as above, product name: KBM-402), 2-(3,4-epoxycyclohexyl)ethyltrimethoxysilane (same as above, product name: KBM-303), 2-(3,4-epoxycyclohexyl)ethyltriethoxysilane, 8-glycidoxyoctyltrimethoxysilane (same as above, product name: KBM-4803), [(3-ethyl-3-oxetanyl)methoxy]propyltrimethoxysilane, and [(3-ethyl-3-oxetanyl)methoxy]propyltriethoxysilane.

In a case where the R^{y} group contains an acryloyl group or a methacryloyl group, it is preferably a group selected from Formula (3a) or (4a).

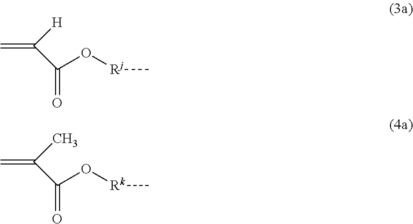

(In the formulae, R^{j} and R^{k} each independently represent a linking group or a divalent organic group. Broken lines represent a bond).

In where R^{j} and R^{k} are a divalent organic group, preferred examples thereof include again those exemplified above as the preferred groups in R^{g}, R^{h}, Rⁱ, R^{j}, and R^{k}.

Examples of the alkoxysilane as a raw material for the particularly preferred one among the repeating units of Formula (2) include 3-methacryloxypropyltrimethoxysilane (manufactured by Shinetsu Chemical Industry Co., Ltd., product name: KBM-503). 3-methacryloxypropyltriethoxysilane (same as above, product name: KBE-503), 3-methacryloxypropylmethyldimethoxysilane (same as above, product name: KBM-502), 3-methacryloxypropylmethyldiethoxysilane (same as above, product name: KBE-502), 3-acryloxypropyltrimethoxysilane (same as above, product name: KBM-5103), and 8-methacryloxyoctyltrimethoxysilane (same as above, product name: KBM-5803).

[Constitutional Unit Represented by Formula (3)]

[SiO_{4/2}] (3)

Since the constitutional unit represented by Formula (3) has a structure similar to SiO₂ in which organic components are eliminated as many as possible, heat resistance and transparency can be imparted to the cured film obtained from the resin composition. In addition, as already described above, the resin composition in which the polysiloxane compound is formed in combination with the constitutional unit represented by Formula (1) is excellent in organic solvent resistance.

The constitutional unit represented by Formula (3) can be obtained by hydrolyzing, as a raw material, a tetraalkoxysilane, a tetrahalosilane (for example, tetrachlorosilane, tetramethoxysilane, tetraethoxysilane, tetra-n-propoxysilane, or tetraisopropoxysilane), or an oligomer thereof and then performing polymerization (see “Polymerization method” described later).

Examples of the oligomer include Silicate 40 (a pentamer on average, manufactured by Tama Chemicals Co., Ltd.), Ethyl silicate 40 (a pentamer on average, manufactured by Colcoat Co., Ltd.), Silicate 45 (a heptamer on average, manufactured by Tama Chemicals Co., Ltd.), M silicate 51 (a tetramer on average, manufactured by Tama Chemicals Co., Ltd.), Methyl silicate 51 (a tetramer on average, manufactured by Colcoat Co., Ltd.), Methyl silicate 53A (a heptamer on average, manufactured by Colcoat Co., Ltd.), Ethyl silicate 48 (a decamer on average, manufactured by Colcoat Co., Ltd.), and a silicate compound such as EMS-485 (a mixture of ethyl silicate and methyl silicate, manufactured by Colcoat Co., Ltd.). From the viewpoint of easiness of handling, the silicate compound is suitably used.

In a case where the total Si atoms of the polysiloxane compound of the component (A) is set to 100% by mole, regarding the proportion of Si atoms of the constitutional unit represented by Formula (1), and Formula (2), and Formula (3), the proportion of Si atoms of the constitutional unit represented by Formula (1) is preferably in a range of 1% to 80% by mole, the proportion of Si atoms of the constitutional unit represented by Formula (2) is preferably in a range of 1% to 80% by mole, and the proportion of Si atoms of the constitutional unit represented by Formula (3) is preferably in a range of 1% to 80% by mole. Specifically, the proportion of Si atoms of the constitutional unit represented by Formula (1) is more preferably in a range of 2% to 60% by mole, the proportion of Si atoms of the constitutional unit represented by Formula (2) is more preferably in a range of 2% to 70% by mole, and the proportion of Si atoms of the constitutional unit represented by Formula (3) is more preferably in a range of 5% to 70% by mole. The proportion of Si atoms of the constitutional unit represented by Formula (1) is still more preferably in a range of 5% to 55% by mole, the proportion of Si atoms of the constitutional unit represented by Formula (2) is still more preferably in a range of 5% to 40% by mole, and the proportion of Si atoms of the constitutional unit represented by Formula (3) is still more preferably in a range of 5% to 40% by mole The % by mole of the Si atoms can be obtained from, for example, the peak area ratio in ²⁹Si-NMR.

[Another Constitutional Unit (Optional Component)]

In the polysiloxane compound of the component (A), for the purpose of adjusting the solubility in the solvent which is the component (B), the heat resistance or the transparency of a cured film to be obtained, or the like, another constitutional unit containing a Si atom may be contained in addition to the constitutional units represented by Formulae (1), (2), and (3). Examples of chlorosilane or alkoxysilane as another constitutional unit are as follows. The chlorosilane and the alkoxysilane described above may be referred to as “other Si monomers”.

Specific examples of the chlorosilane include dimethyldichlorosilane, diethyldichlorosilane, dipropyldichlorosilane, diphenyldichlorosilane, bis(3,3,3-trifluoropropyl)dichlorosilane, methyl(3,3,3-trifluoropropyl)dichlorosilane, methyltrichlorosilane, ethyltrichlorosilane, propyltrichlorosilane, isopropyltrichlorosilane, phenyltrichlorosilane, methylphenyltrichlorosilane, trifluoromethyltrichlorosilane, pentafluoroethyltrichlorosilane, and 3,3,3-trifluoropropyltrichlorosilane.

Specific examples of the alkoxysilane include dimethyldimethoxysilane, dimethyldiethoxysilane, dimethyldipropoxysilane, dimethyldiphenoxysilane, diethyldimethoxysilane, diethyldiethoxysilane, diethyldipropoxysilane, diethyldiphenoxysilane, dipropyldimethoxysilane, dipropyldiethoxysilane, diphenyldimethoxysilane, diphenyldiethoxysilane, diphenyldiphenoxysilane, bis(3,3,3-trifluoropropyl)dimethoxysilane, methyl(3,3,3-trifluoropropyl)dimethoxysilane, methyltrimethoxysilane, methylphenyltridixisilane, ethyltrimethoxysilane, propyltrimethoxysilane, isopropyltrimethoxysilane, phenyltrimethoxysilane, methyltriethoxysilane, methylphenyldiethoxysilane, ethyltriethoxysilane, propyltriethoxysilane, isopropyltriethoxysilane, phenyltriethoxysilane, methyltripropoxysilane, ethyltripropoxysilane, propyltripropoxysilane, isopropyltripropoxysilane, phenyltripropoxysilane, methyltriisopropoxysilane, ethyltriisopropoxysilane, propyltriisopropoxysilane, isopropyltriisopropoxysilane, phenyltriisopropoxysilane, trifluoromethyltrimethoxysilane, pentafluoroethyltrimethoxysilane, 3,3,3-trifluoropropyltrimethoxysilane, and 3,3,3-trifluoropropyltriethoxysilane.

The chlorosilane or alkoxysilane may be used alone or in a combination of two or more thereof.

Among them, phenyltrimethoxysilane, phenyltriethoxysilane, methylphenyldimethoxysilane, or methylphenyldiethoxysilane is preferable for the purpose of improving heat resistance and transparency of a cured film to be obtained, and dimethyldimethoxysilane or dimethyldiethoxysilane is preferable for the purpose of improving flexibility, preventing cracking, or the like of a cured film to be obtained.

In a case where the total Si atoms of the polysiloxane compound of the component (A) is set to 100% by mole, the proportion of the constitutional unit obtained from chlorosilane and alkoxysilane, which are the other Si monomers, is, for example, 0% to 95% by mole and preferably 10% to 85% by mole.

Example 22 (the content of the phenyltriethoxysilane used in terms of the Si atom: 85% by mole) and Example 23 (same as above: 90% by mole), which will be described later, exhibit resistance to PGMEA and NMP, but Comparative Example 3 (same as above: 90% by mole) which is outside the scope of the present invention does not exhibit such a resistance. That is, it is clear from the experimental data that the effect of the present invention is obtained even in a case where the content of the constitutional unit obtained from phenyltriethoxysilane other than the constitutional units other than Formulae (1), (2), and (3) is as high as 85% to 90% by mole.

The molecular weight of the polysiloxane compound which is the component (A) is generally in a range of 700 to 100,000, preferably in a range of 800 to 10,000, and more preferably in a range of 1,000 to 6,000 in terms of the weight-average molecular weight. Basically, the molecular weight can be controlled by adjusting the amount of the catalyst and the temperature of the polymerization reaction.

[Polymerization Method]

Next, a polymerization method for obtaining the polysiloxane compound which is the component (A) will be described. The polysiloxane compound which is the component (A) can be obtained by the hydrolysis and polycondensation reaction using halosilanes which are represented by Formula (6), for obtaining the constitutional units represented by Formulae (1), (2), and (3), an alkoxysilane represented by Formula (7), and the other Si monomers.

The present hydrolysis and polycondensation reaction can be carried out by a general method in the hydrolysis and condensation reaction of halosilanes (preferably chlorosilane) and an alkoxysilane. A specific example of the method is performed as follows. First, a predetermined amount of the halosilanes and the alkoxysilane are collected in a reaction vessel at room temperature (particularly, which means the ambient temperature without heating or cooling and is generally about 15° C. or higher and about 30° C. or lower. The same is applied hereinafter), and then water for hydrolyzing the halosilanes and the alkoxysilane, a catalyst for advancing the polycondensation reaction, and a reaction solvent as desired are added into the reactor to prepare a reaction solution. The order of charging the reaction materials is not limited to the order described above, and the reaction materials can be charged in any order to prepare the reaction solution. In addition, in a case where the other Si monomers are used in combination, the other Si monomers may be added into the reactor in the same manner as in the case of the halosilanes and the alkoxysilane. Next, the hydrolysis and condensation reaction is advanced at a predetermined temperature for a predetermined time while stirring the reaction solution, whereby the polysiloxane compound which is the component (A) can be obtained. The time required for the hydrolysis and condensation depends on the kind of catalyst, but it is generally 3 hours or more and 24 hours or less, and the reaction temperature is equal to or higher than the room temperature (25° C.) and equal to or lower than 200° C. In a case of performing heating, the reaction vessel is preferably to be a closed type or it is preferable to reflux the reaction system by attaching a reflux device such as a condenser to prevent unreacted raw materials, water, a reaction solvent, and/or a catalyst in the reaction system from being distilled off out of the reaction system. After the reaction, from the viewpoint of handling the polysiloxane compound which is the component (A), it is preferable to remove water remaining in the reaction system, an alcohol produced, and a catalyst. The water, the alcohol, and the catalyst may be removed by an extraction operation, or a solvent such as toluene that does not adversely affect the reaction may be added into the reaction system and azeotropically removed with a Dean-Stark tube.

The amount of water that is used in the hydrolysis and condensation reactions is not particularly limited. From the viewpoint of reaction efficiency, the amount of water is preferably 0.5 times to 5 times the total number of moles of the hydrolyzable groups (an alkoxy group and a halogen atomic group) contained in the alkoxysilane and the halosilanes which are raw materials.

The catalyst for advancing the polycondensation reaction is not particularly limited, but an acid catalyst or a base catalyst is preferably used. Specific examples of the acid catalyst include hydrochloric acid, nitric acid, sulfuric acid, fluoric acid, phosphoric acid, acetic acid, oxalic acid, trifluoroacetic acid, methanesulfonic acid, trifluoromethanesulfonic acid, camphorsulfonic acid, benzenesulfonic acid, tosylic acid, formic acid, a polyvalent carboxylic acid, and an anhydride thereof. Specific examples of the base catalyst include triethyl amine, tripropyl amine, tributyl amine, tripentyl amine, trihexyl amine, triheptyl amine, trioctyl amine, diethyl amine, triethanol amine, diethanol amine, sodium hydroxide, potassium hydroxide, sodium carbonate, and tetramethylammonium hydroxide. The amount of the catalyst used is preferably 1.0×10⁻⁵ times to 1.0×10⁻¹ times the total number of moles of the hydrolyzable groups (an alkoxy group and a halogen atomic group) contained in the alkoxysilane and the halosilanes which are raw materials.

In the hydrolysis and condensation reaction, it is not always necessary to use a reaction solvent, and raw material compounds, water, and a catalyst can be mixed and hydrolyzed and condensed. On the other hand, in a case where a reaction solvent is used, the kind thereof is not particularly limited. Among the above, a polar solvent is preferable and an alcohol solvent is more preferable, from the viewpoint of solubility of a raw material compound, water, and a catalyst. Specific examples thereof include methanol, ethanol, 1-propanol, 2-propanol, 1-butanol, 2-butanol, diacetone alcohol, and propylene glycol monomethyl ether. As the amount to be used in a case where the above reaction solvent is used, any amount necessary for the hydrolysis and condensation reaction to proceed in a homogeneous system can be used. In addition, a solvent which is the component (B) described later may be used as the reaction solvent.

[Component (B)]

The solvent which is the component (B) is particularly limited as long as it can dissolve a photosensitizer selected from a polysiloxane compound which is the component (A), a quinone diazide compound which the component (C) which will be described later, an acid generator, and a radical generator. Specific examples thereof include propylene glycol monomethyl ether acetate, propylene glycol monomethyl ether, cyclohexanone, ethyl lactate, γ-butyrolactone, diacetone alcohol, diglyme, methyl isobutyl ketone, 3-methoxybutyl acetate, 2-heptanone, N,N-dimethylformamide, N,N-dimethylacetamide, N-methylpyrrolidone, glycols, glycol ethers, and glycol ether esters, but the specific examples are not limited thereto.

Specific examples of the glycol, glycol ether, and glycol ether ester include CELTOL (registered trade mark) manufactured by Daicel Corporation and Highsolve (registered trade mark) manufactured by TOHO Chemical Industry Co., Ltd. Specific examples thereof include cyclohexanol acetate, dipropylene glycol dimethyl ether, propylene glycol diacetate, dipropylene glycol methyl-n-propyl ether, dipropylene glycol methyl ether acetate, 1,4-butanediol diacetate, 1,3-butylene glycol diacetate, 1,6-hexanediol diacetate, 3-methoxybutyl acetate, ethylene glycol monobutyl ether acetate, diethylene glycol monoethyl ether acetate, diethylene glycol monobutyl ether acetate, triacetin, 1,3-butylene glycol, propylene glycol-n-propyl ether, propylene glycol-n-butyl ether, dipropylene glycol methyl ether, dipropylene glycol ethyl ether, dipropylene glycol-n-propyl ether, dipropylene glycol-n-butyl ether, tripropylene glycol methyl ether, tripropylene glycol-n-butyl ether, triethylene glycol dimethyl ether, diethylene glycol butyl methyl ether, tripropylene glycol dimethyl ether, and triethylene glycol dimethyl ether, but the specific examples are not limited thereto.

The composition ratio of the solvent which is the component (B) in the resin composition is generally 40% by mass or more and 95% by mass or less and preferably 50% by mass or more and 90% by mass or less. In a case where the composition ratio of the solvent is appropriately adjusted, it is easy to perform coating and film formation into a uniform resin film having an appropriate film thickness.

[Additive (Optional Component)]

The following components can be contained as an additive in the resin composition as long as the above-described excellent properties of the resin composition are not significantly impaired.

For example, an additive such as a surfactant can be added for the purpose of improving coatability, levelability, film forming property, storage stability, or defoaming property. Specific examples thereof include commercially available surfactants such as trade name MEGAFACE, product number F142D, F172, F173, or F183, manufactured by DIC Corporation; trade name Florard, product number, FC-135, FC-170C, FC-430, or FC-431, manufactured by Sumitomo 3M Limited; trade name Surflon, product number S-112, S-113, S-131, S-141, or S-145, manufactured by AGC SEIMI CHEMICAL Co., Ltd.; and trade name SH-28PA, SH-190, SH-193, SZ-6032, or SF-8428, manufactured by Dow Toray Co., Ltd. These surfactants are not essential components of the resin composition, but in a case where they are added, the blending amount thereof is generally 0.001 part by mass or more and 10 parts by mass or less with respect to 100 parts by mass of the polysiloxane compound which is the component (A). MEGAFACE is the trade name of the fluorine-based additive (surfactant or surface modifier) manufactured by DIC Corporation, Florard is the trade name of the fluorine-based surfactant manufactured by Sumitomo 3M Limited, and Surflon is the trade name of the fluorine-based surfactant manufactured by AGC SEIMI CHEMICAL Co., Ltd., each of which is registered as a trade mark.

As other components, a curing agent can be blended for the purpose of improving the chemical liquid resistance of the cured film. Examples of the curing agent include a melamine curing agent, a urea resin curing agent, a polybasic acid curing agent, an isocyanate curing agent, and an epoxy curing agent. It is presumed that the curing agent mainly reacts with “—OH” of the repeating unit of the polysiloxane compound, where the repeating unit is the component (A), to form a crosslinked structure.

Specific examples thereof include isocyanates such as isophorone diisocyanate, hexamethylene diisocyanate, tolylene diisocyanate, and diphenylmethane diisocyanate, and isocyanurates, blocked isocyanates, or biurets of the isocyanates; amino compounds such as melamine resins such as an alkylated melamine, methylol melamine, and imino melamine or urea resins; and an epoxy curing agent having two or more epoxy groups, which is obtained by the reaction of a multivalent phenol such as bisphenol A with epichlorohydrin.

Specifically, a curing agent having a structure represented by Formula (8) is more preferable, and specific examples thereof include melamine derivatives or urea derivatives represented by Formulae (8a) to (8d) (trade name, manufactured by Sanwa Chemical Co., Ltd.) (in Formula (8), broken lines mean a bond).

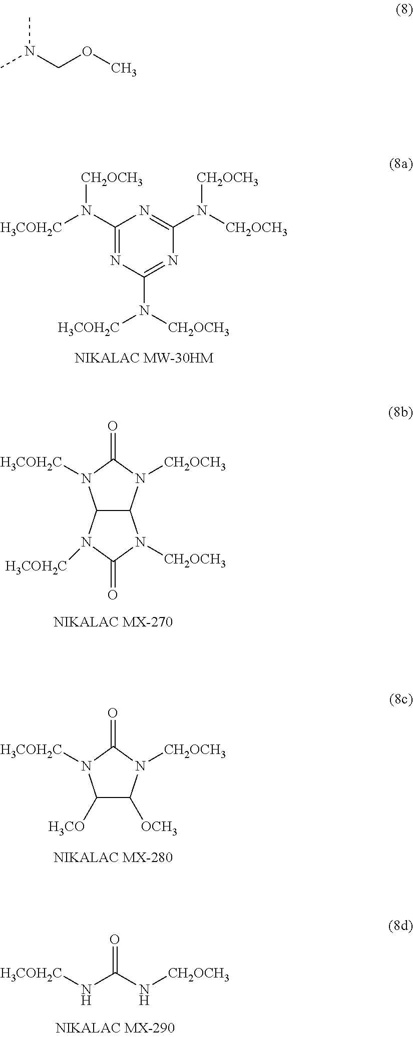

These curing agents are not essential components of the resin composition, but in a case where they are added, the blending amount thereof is generally 0.001 part by mass and 10 parts by mass or less with respect to 100 parts by mass of the polysiloxane compound which is the component (A).

<2> A Photosensitive Resin Composition Further Containing a Component (C)

In a case where a photosensitizer selected from a quinone diazide compound, a photoacid generator, and a photoradical generator is incorporated as the component (C) in the “resin composition containing the component (A) and the component (B)”, a photosensitive resin composition can be obtained. Hereinafter, the quinone diazide compound, the photoacid generator, and the photoradical generator will be described in order.

In a case of being exposed to light, the quinone diazide compound releases a nitrogen molecule and decomposes, and a carboxylic acid group is generated in the molecule of quinone diazide compound, thereby improving the solubility of the photosensitive resin film in an alkaline developing solution. In addition, the alkali solubility of the photosensitive resin film is suppressed in the unexposed portion. As a result, a photosensitive resin composition containing the quinone diazide compound produces a contrast in the solubility in the alkaline developing solution in the unexposed portion and the exposed portion, and a positive type pattern can be formed. The kind of quinone diazide compound is not particularly limited. Preferred examples thereof include a quinone diazide compound in which a naphthoquinone diazide sulfonic acid is ester-bonded to a compound having at least a phenolic hydroxy group. Specific examples thereof include a quinone diazide compound in which a naphthoquinone diazide sulfonic acid is ester-bonded to a compound in which the ortho-position and the para-position of the phenolic hydroxy group are each independently any one of a hydrogen atom, a hydroxy group, or a substituent represented by Formula (9):

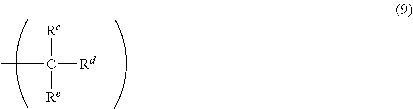

Here, R^{c}, R^{d}, and R^{e} in Formula (9) each independently represents any one of an alkyl group having 1 to 10 carbon atoms, a carboxyl group, a phenyl group, and a substituted phenyl group.

In Formula (9), the alkyl group having 1 to 10 carbon atoms may be any one of an unsubstituted group or a substituted group. Specific examples of this alkyl group include a methyl group, an ethyl group, an n-propyl group, an isopropyl group, an n-butyl group, an isobutyl group, a t-butyl group, an n-hexyl group, a cyclohexyl group, an n-heptyl group, an n-octyl group, a trifluoromethyl group, and a 2-carboxyethyl group.

In Formula (9), examples of the kind of the substituent of the substituted phenyl group include a hydroxy group and a methoxy group. The number and substitution positions of these substituents are not particularly limited.

These quinone diazide compounds can be synthesized by a conventionally known esterification reaction of a compound having at least a phenolic hydroxy group with naphthoquinone diazide sulfonic acid chloride.

Specific examples of the compound having at least a phenolic hydroxy group include the following compounds.

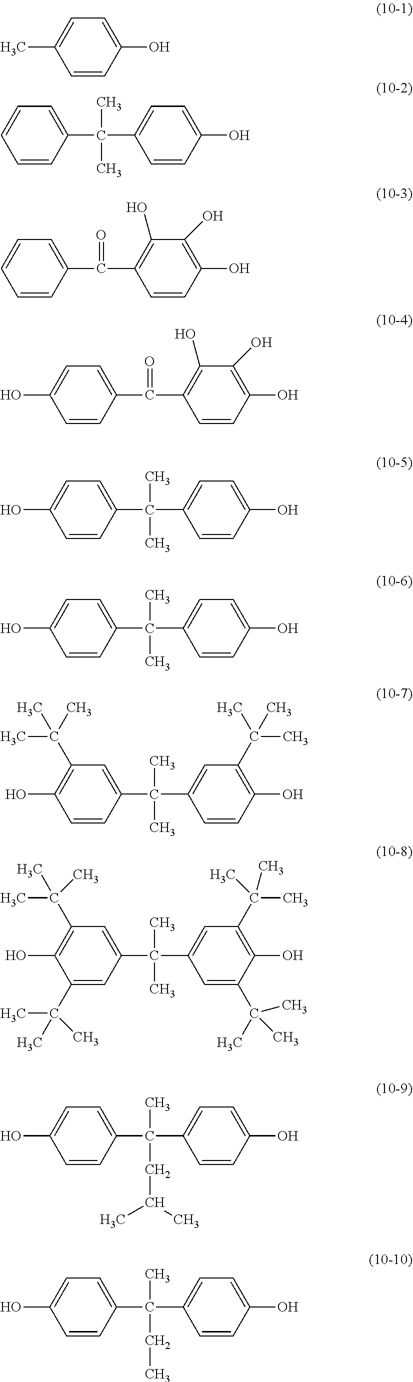

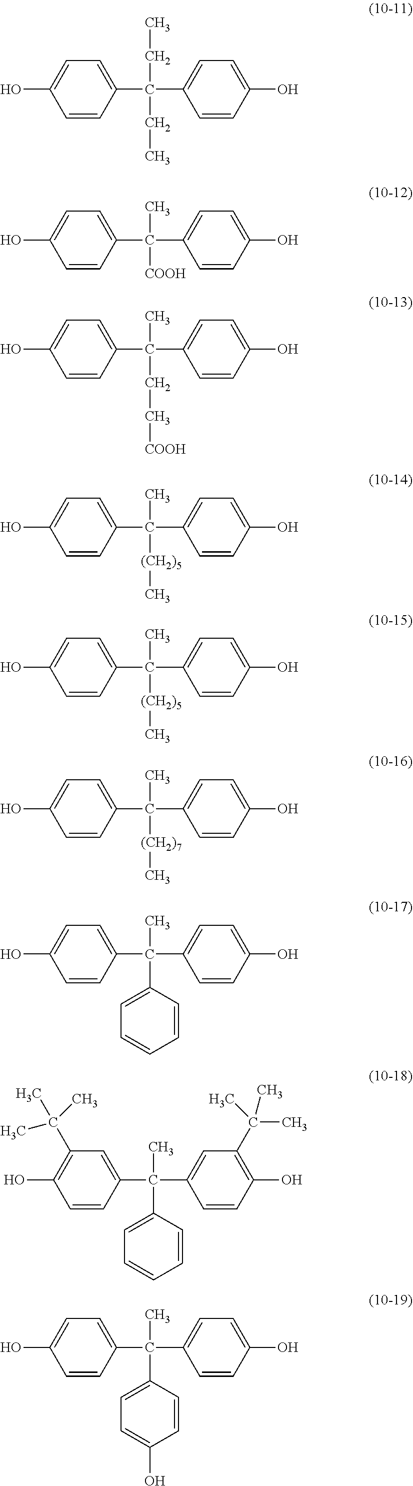

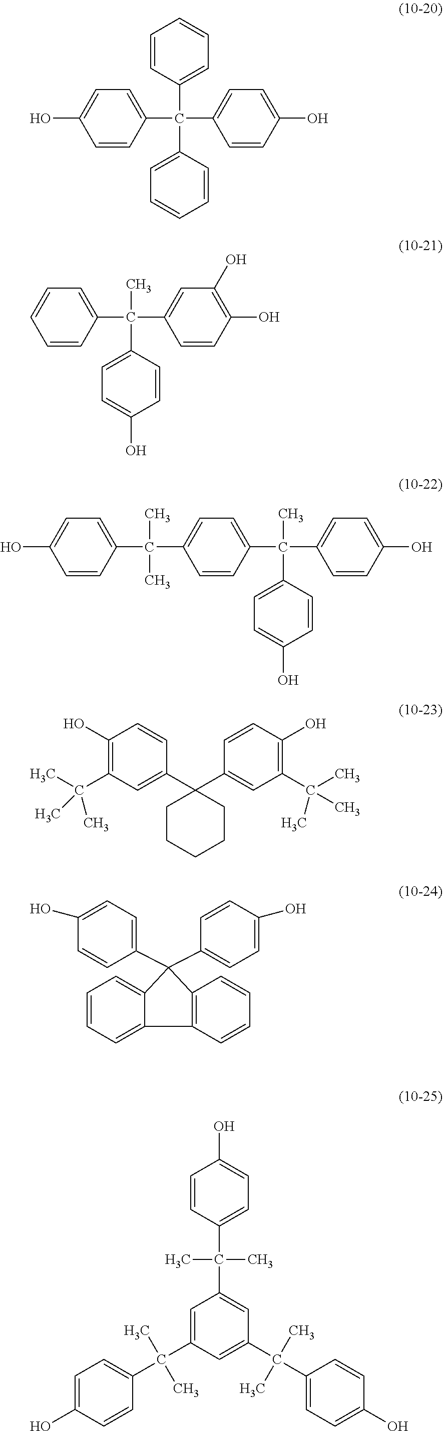 [SMILES: Oc1ccc(C(c2ccccc2)(c2ccccc2)c2ccc(O)cc2)cc1 ; CC(c1ccccc1)(c1ccc(O)cc1)c1ccc(O)c(O)c1 ; CC(C)(c1ccc(O)cc1)c1ccc(C(C)(c2ccc(O)cc2)c2ccc(O)cc2)cc1 ; CC(C)(C)c1cc(C2(c3ccc(O)c(C(C)(C)C)c3)CCCCC2)ccc1O ; Oc1ccc(C2(c3ccc(O)cc3)c3ccccc3-c3ccccc32)cc1 ; CC(C)(c1ccc(O)cc1)c1cc(C(C)(C)c2ccc(O)cc2)cc(C(C)(C)c2ccc(O)cc2)c1]

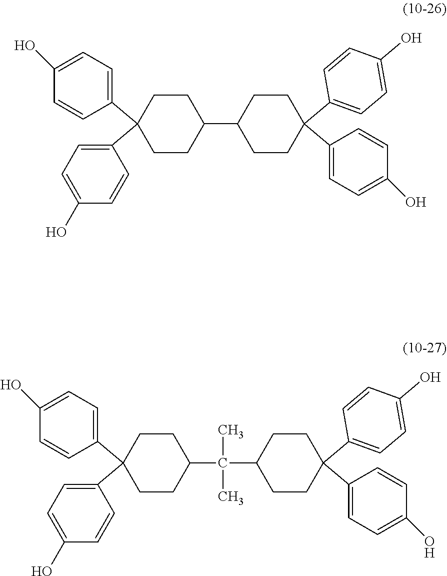 [SMILES: Oc1ccc(C2(c3ccc(O)cc3)CCC(C3CCC(c4ccc(O)cc4)(c4ccc(O)cc4)CC3)CC2)cc1 ; CC(C)(C1CCC(c2ccc(O)cc2)(c2ccc(O)cc2)CC1)C1CCC(c2ccc(O)cc2)(c2ccc(O)cc2)CC1]

As the naphthoquinone diazide sulfonic acid chloride, 5-naphthoquinone diazide sulfonic acid chloride represented by Formula (11-1) or 4-naphthoquinone diazide sulfonic acid chloride represented by Formula (11-2) can be used.

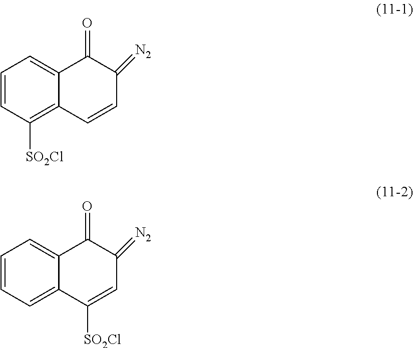

In the present specification, the compound synthesized by the esterification reaction of 4-naphthoquinone diazide sulfonic acid chloride with the compound having at least the phenolic hydroxy group may be referred to as a “4-naphthoquinone diazide sulfonic acid ester compound”. In addition, the compound synthesized by the esterification reaction of 5-naphthoquinone diazide sulfonic acid chloride with the compound having at least the phenolic hydroxy group may be referred to as a “5-naphthoquinone diazide sulfonic acid chloride”.

Since the 4-naphthoquinone diazide sulfonic acid ester compound has an absorption spectrum in the i-line (wavelength: 365 nm) range, it is suitable for the i-line exposure. In addition, since the 5-naphthoquinone diazide sulfonic acid ester compound has an absorption spectrum in a wide wavelength range, it is suitable for exposure in the wide wavelength range. The quinone diazide compound is preferably selected from the 4-naphthoquinone diazide sulfonic acid ester compound or the 5-naphthoquinone diazide sulfonic acid ester compound depending on the wavelength of light with which exposure is performed. The 4-naphthoquinone diazide sulfonic acid ester compound and the 5-naphthoquinone diazide sulfonic acid ester compound can also be mixed and used.

A preferred example of the quinone diazide compound is a compound obtained by esterification reaction of a compound having a phenolic hydroxy group represented by Formulae (10-1), (10-2), (10-3), (10-4), (10-17), (10-19), (10-21), or (10-22) with naphthoquinone diazide sulfonic acid chloride represented by Formulae (11-1) and (11-2).

These quinone diazide compounds are commercially available, and specific examples of the commercially available compound include NT series (manufactured by Toyo Gosei Co., Ltd.), 4NT series (same as above), PC-5 (same as above), TKF series (SANBO CHEMICAL Ind. Co., Ltd.), and PQ-C (same as above).

The composition ratio of the quinone diazide compound as the component (C) in the photosensitive resin composition is not necessarily limited, but for example, a preferred aspect is 2% by mass or more and 40% by mass or less, and a more preferred aspect is 5% by mass or more and 30% by mass or less, in a case where the polysiloxane compound which is the component (A) is set to 100% by mass. In a case where an appropriate amount of the quinone diazide compound is used, it is easy to achieve both sufficient patterning performance and storage stability of the composition.

Next, the photoacid generator will be described. The photoacid generator is a compound that generates an acid by irradiation with light, and the acid generated in the exposed portion acts on the acid-labile group introduced into an X group in Formula (1), whereby the X group is converted to a hydrogen group and solubility in an alkaline developing solution is can be obtained. On the other hand, since this action does not occur in the unexposed portion and solubility in the alkaline developing solution is not obtained, a pattern is formed.

Specific examples of the photoacid generator include a sulfonium salt, an iodonium salt, sulfonyl diazomethane, N-sulfonyloxyimide, and oxime-O-sulfonate. These photoacid generators may be used alone or in a combination of two or more thereof. Specific examples of the commercially available products include trade names Irgacure PAG121, Irgacure PAG103, Irgacure CGI1380, and Irgacure CGI725 (all manufactured by BASF USA Ltd.); trade names: PAI-101, PAI-106, NAI-105, NAI-106, TAZ-110, and TAZ-204 (all manufactured by Midori KagakuCo., Ltd.); trade names CPI-200K, CPI-2105, CPI-101A, CPI-110A, CPI-100P, CPI-110P, CPI-100TF, CPI-110TF, HS-1, HS-1A, HS-1P, HS-1N, HS-1TF, HS-1NF, HS-1MS, HS-1CS, LW-S1, and LW-S1NF (all manufactured by San-Apro Ltd.); and trade names TFE-triazine, TME-triazine, and MP-triazine (all manufactured by Sanwa Chemical Co., Ltd.). However, the specific examples are not limited thereto.

The composition ratio of the photoacid generator as the component (C) in the photosensitive resin composition is not necessarily limited, but for example, a preferred aspect is 0.01% by mass or more and 10% by mass or less, and a more preferred aspect is 0.05% by mass or more and 5% by mass or less, in a case where the polysiloxane compound which is the component (A) is set to 100% by mass. In a case where an appropriate amount of the photoacid generator is used, it is easy to achieve both sufficient patterning performance and storage stability of the composition.

Next, the photoradical generator will be described. The photoradical generator is a compound that generates radicals by irradiation with light, and the radicals generated in the exposed portion cause the radically polymerization reaction at the carbon-carbon double bond in an acryloyl group and a methacryloyl group contained in R^{y} in Formula (2), whereby a cross-linking reaction proceeds to impart good chemical liquid resistance to the cured film.

Specific examples of the photoradical initiator include acetophenone, propiophenone, benzophenone, xanthol, fluorene, benzaldehyde, anthracinone, triphenyl amine, carbazole, 3-methylacetophenone, 4-methylacetophenone, 3-pentylacetophenone, 2,2-diethoxyacetophenone, 4-methoxyacetophenone, 3-bromoacetophenone, 4-allylacetophenone, p-diacetylbenzene, 3-methoxybenzophenone, 4-methylbenzophenone, 4-chlorobenzophenone, 4,4′-dimethoxybenzophenone, 4-chloro-4′-benzylbenzophenone, 3-chloroxanthone, 3,9-dichloroxanthone, 3-chloro-8-nonylxanthone, benzoin, benzoin methyl ether, benzoin butyl ether, bis(4-dimethylaminophenyl) ketone, benzylmethoxyketal, 2-chlorothioxanthone, 2,2-dimethoxy-1,2-diphenylacetophenon-1-one (trade name IRGACURE 651, manufactured by BASF Japan Ltd.), 1-hydroxy-cyclohexyl-phenyl-ketone (trade name IRGACURE 184, manufactured by BASF Japan Ltd.), 2-hydroxy-2-methyl-1-phenyl-propan-1-one (trade name DAROCUR 1173, manufactured by BASF Japan Ltd.), 1-[4-(2-hydroxyethoxy)-phenyl]-2-hydroxy-2-methyl-1-propan-1-one (trade name IRGACURE 2959, manufactured by BASF Japan Ltd.), 2-methyl-1-[4-(methylthio)phenyl]-2-morpholinopropan-1-one (trade name IRGACURE 907, manufactured by BASF Japan Ltd.), 2-benzyl-2-dimethylamino-1-(4-morpholinophenyl)-butanon-1-one (trade name IRGACURE 369, manufactured by BASF Japan Ltd.), 2-(4-methylbenzyl)-2-dimethylamino-1-(4-morpholin-4-yl-phenyl)-b utan-1-one (trade name IRGACURE 379, manufactured by BASF Japan Ltd.), and dibenzoyl.

Further, examples of the initiator capable of suppressing oxygen inhibition on the surface of the cured product, include as a photoradical initiator having two or more photodegradable groups in the molecule, 2-hydroxy-1-[4-[4-(2-hydroxy-2-methyl-propionyl)-benzyl]phenyl]-2-methyl-propan-1-one (trade name IRGACURE 127, manufactured by BASF Japan Ltd.), 1-[4-(4-benzoixylphenylsulfanyl)phenyl]-2-methyl-2-(4-methylphen ylsulfonyl)propan-1-one (trade name ESURE 1001M), methylbenzoyl formate (trade name SPEEDCURE MBF, manufactured by LAMBSON Ltd.), 0-ethoxyimino-1-phenylpropan-1-one (trade name SPEEDCURE PDO, manufactured by LAMBSON Ltd.), and oligo [2-hydroxy-2-methyl-[4-(1-methylvinyl)phenyl] propanone (trade name ESCURE KIP150, manufactured by LAMBERTI S.p.A.); and as a hydrogen abstraction type photoinitiator having three aromatic rings in the molecule, 1-[4-(phenylthio)-, 2-(0-benzoyloxime)] 1,2-octanedione (trade name: IRGACURE OXE 01, manufactured by BASF Japan Ltd.), 1-[9-ethyl-6-(2-methylbenzoyl)-9H-carbazol-3-yl]-1-(0)-acetyloxime)etanone (trade name IRGACURE OXE 02, manufactured by BASF Japan Ltd.), 4-benzoyl-4′methyldiphenylsulfide, 4-phenylbenzophenone, and 4,4′,4″-(hexamethyltriamino)triphenylmethane. In addition, examples thereof include acyl phosphine oxide-based photoradical initiators such as 2,4,6-trimethylbenzoyl-diphenyl-phosphine oxide (trade name: DAROCUR TPO, manufactured by BASF Japan Ltd.), bis(2,4,6-trimethylbenzoyl)-phenylphosphine, and bis(2,6-dimethylbenzoyl)-2,4,4-trimethyl-pentylphosphine oxide (trade name IRGACURE 819, manufactured by BASF Japan Ltd.), which are characterized by improved curability in the deep portion.

These photoradical initiators may be used alone, may be used as a mixture of two or more thereof, or may be in combination with other compounds.

Specific examples of the combination with other compounds include a combination with 4,4′-bis(dimethylamino)benzophenone, 4,4′-bis(diethylamino)benzophenone, diethanolmethyl amine, dimethylethanol amine, triethanol amine, ethyl-4-dimethylaminobenzoate, and 2-ethylhexyl-4-dimethylaminobenzoate; a combination further combined thereto with an iodonium salt such as diphenyliodonium chloride or a combination further combined thereto with a dye such as methylene blue and an amine.

The composition ratio of the photoradical generator as the component (C) in the photosensitive resin composition is not necessarily limited, but for example, a preferred aspect is 0.01% by mass or more and 10% by mass or less, and a more preferred aspect is 0.05% by mass or more and 5% by mass or less, in a case where the polysiloxane compound which is the component (A) is set to 100% by mass. In a case where the photoradical generator is used according to the amount described here, it is possible to further improve the balance between the chemical liquid resistance of the cured film and the storage stability of the composition.

The photosensitive resin composition may contain additives such as coatability, levelability, film forming property, and surfactant described in <1> described above. As the kind and the amount of each preferred compound, those described in <1> can be mentioned again.

<3> Method for Manufacturing a Cured Film of a Resin Composition

As the substrate that is coated with the resin composition, a substrate made of silicon wafer, metal, glass, ceramic, or plastic is selected depending on the intended use of the cured film to be formed.

As the coating method, a conventionally known coating method such as spin coating, dip coating, spray coating, bar coating, or a method using an applicator, inkjet, or roll coater can be used without particular limitation.

Thereafter, the substrate coated with the composition is generally heated at 80° C. to 120° C. for 30 seconds or more and 5 minutes or less to obtain a resin film. A cured film can be obtained by further heat-treating the resin film. The heating treatment temperature is generally 350° C. or lower. It is not necessary to perform heating at 350° C. or higher, and a more preferable temperature is 150° C. or higher and 280° C. or lower, depending on the boiling point of the solvent. In a case where the heating treatment is performed in the above temperature range, a cured film can be obtained by a dehydration condensation reaction of a silanol group of the polysiloxane compound which is the component (A) and a curing reaction of an epoxy group or an oxetane group. In a case where the temperature is lower than 80° C., it takes a long time for drying, and in a case where the temperature is higher than 280° C., the uniformity of the surface of the formed cured film may be impaired. The heating time is 30 seconds or more and 90 minutes or less. In a case where heating time is less than 30 seconds, the solvent may remain in the cured film, while it is not necessary to heat for more than 90 minutes.

The photosensitive resin composition may further contain a sensitizer. Ina case where the sensitizer is contained, the reaction of the photosensitizer which is the component (C) is promoted in the exposure treatment, and thus the sensitivity and the pattern resolution are improved.

The sensitizer is not particularly limited, but a sensitizer that vaporizes by heat treatment and fades by irradiation with light is preferably used. The sensitizer needs to have a light absorption spectrum for the exposure wavelengths (for example, 365 nm (i-line), 405 nm (h-line), 436 nm (g-line)) in the exposure step, but in a case where this sensitizer remains in the cured film as it is, the transparency is decreased due to the presence of absorption spectrum in the visible light range. Therefore, in order to prevent the decrease in transparency due to the sensitizer, the sensitizer to be used is preferably a compound that vaporizes by heat treatment such as thermosetting or a compound that fades by irradiation with light such as bleaching exposure which will be described later.

Specific examples of the sensitizer that vaporizes by the heat treatment described above and fades by irradiation with light include coumarin such as 3,3′-carbonylbis(diethylaminocoumarin); anthracene such as 9,10-anthracene; aromatic ketones such as benzophenone, 4,4′-dimethoxybenzophenone, acetophenone, 4-methoxyacetophenone, and benzaldehyde; and condensed aromatic compound such as biphenyl, 1,4-dimethylnaphthalene, 9-fluorenone, fluorene, phenanthrene, triphenylene, pyrene, anthracene, 9-phenylanthracene, 9-methoxyanthracene, 9,10-diphenylanthracene, 9,10-bis(4-methoxyphenyl)anthracene, 9,10-bis(triphenylsilyl)anthracene, 9,10-dimethoxyanthracene, 9,10-diethoxyanthracene, 9,10-dipropoxyanthracene, 9,10-dibutoxyanthracene, 9,10-dipentaoxyanthracene, 2-t-butyl-9,10-dibutoxyanthracene, and 9,10-bis(trimethylsilylethynyl)anthracene. Examples of the commercially available product include ANTHRACURE (manufactured by Kawasaki Kasei Chemicals Ltd.).

These sensitizers are not essential components of the photosensitive resin composition, but in a case where they are added, the blending amount thereof is generally 0.001 part by mass and 10 parts by mass or less with respect to 100 parts by mass of the polysiloxane compound which is the component (A).

In a case where a photosensitizer selected from a quinone diazide compound, a photoacid generator, and a photoradical generator is used as the component (C) in the photosensitive resin composition, those skilled in the art may appropriately determine whether each thereof is used alone or in a combination of two or more thereof, depending on the intended use, usage environment, or restrictions.

<4> Patterning Method Using a Photosensitive Resin Composition

Next, a patterning method using a photosensitive resin composition (in the present specification, may be also referred to as a “method for producing a patterned cured film”) will be described.

Since the patterned cured film requires an exposure step, it is different from the method for producing the cured film obtained from the resin composition described above. The patterning method will be described below.

The method for producing a patterned cured film can include the following first to fourth steps.

the first step: a step of applying the photosensitive resin composition according to Invention 6 onto a substrate and performing drying to form a photosensitive resin film,

the second step: a step of exposing the photosensitive resin film,

the third step: a step of developing the exposed photosensitive resin film to form a patterned resin film, and

the fourth step: a step of heating the patterned resin film, thereby curing the patterned resin film such that the patterned resin film is converted into a patterned cured film.

[First Step]

As the substrate that is coated with the photosensitive resin composition, a substrate made of silicon wafer, metal, glass, ceramic, or plastic is selected depending on the intended use of the cured film to be formed. As the coating method on the substrate, a conventionally known coating method such as spin coating, dip coating, spray coating, bar coating, or a method using an applicator, inkjet, or roll coater can be used without particular limitation.

Thereafter, the substrate coated with the photosensitive resin composition is generally heated at 80° C. to 120° C. for 30 seconds or more and 5 minutes or less to obtain a photosensitive resin film.

[Second Step]

Next, the photosensitive resin film obtained in the first step is shielded from light by a light-shielding plate (a mask) having a desired shape for forming a targeted pattern and is subjected to an exposure treatment, whereby an exposed photosensitive resin film is obtained.

A conventionally known method can be used for the exposure treatment. As the light source, a light source having a wavelength in the range of 100 to 600 nm can be used. Specifically, a low-pressure mercury lamp, a high-pressure mercury lamp, an ultra-high-pressure mercury lamp, a KrF excimer laser (wavelength: 248 nm), an ArF excimer laser (wavelength: 193 nm), and the like can be used. The exposure amount can be adjusted according to the kind and the amount of the photosensitizer to be used, the manufacturing step, and the like. The exposure amount is not particularly limited; however, it is about 1 to 10,000 mJ/cm² and preferably 10 to 5,000 mJ/cm².

After the exposure, post-exposure heating can be performed before the developing step as necessary. The temperature of post-exposure heating is preferably 60° C. to 180° C., and the time of post-exposure heating is preferably 0.5 to 10 minutes.

[Third Step]

Next, the exposed photosensitive resin film obtained in the second step is subjected to developing, whereby a film having a desired pattern shape (hereinafter, may be referred to as a “patterned resin film”) can be manufactured.

Development is the formation of a pattern by dissolving, cleaning, and removing the exposed portion using an alkaline aqueous solution as a developing solution.

The developing solution to be used is not particularly limited as long as it can remove the photosensitive resin film in the exposed portion by a predetermined developing method. Specific examples thereof include an inorganic alkali, a primary amine, a secondary amine, a tertiary amine, an alcohol amine, a quaternary ammonium salt, and an alkaline aqueous solution using a mixture thereof.

More specific examples thereof include an alkaline aqueous solution of a compound such as potassium hydroxide, sodium hydroxide, ammonia, ethyl amine, diethyl amine, triethyl amine, triethanolamine, or tetramethylammonium hydroxide (abbreviation: TMAH). Among the above, it is preferable to use a TMAH aqueous solution, and in particular, it is preferable to use a TMAH aqueous solution of 0.1% by mass or more and 5% by mass or less and more preferably 2% by mass or more and 3% by mass or less. As the developing method, conventionally known methods such as a dipping method, a paddle method, and a spraying method can be used, and the developing time is generally 0.1 minutes or more and 3 minutes or less and preferably 0.5 minutes or more and 2 minutes or less. Thereafter, as necessary, washing, rinsing, drying and the like can be performed to form a targeted patterned film (hereinafter, a “patterned resin film”) on the substrate.

In a case where a quinone diazide compound is used as the component (C), it is preferable to perform bleaching exposure on the patterned resin film. The purpose is to improve the transparency of the finally obtained patterned cured film by photodecomposing the quinone diazide compound remaining in the patterned resin film (so-called unexposed portion). The bleaching exposure can be performed by the same exposure treatment as that in the second step.

[Fourth Step]

Next, the patterned resin film (including the bleaching-exposed patterned resin film) obtained in the third step is heat-treated to obtain a final patterned cured film. By the heating treatment, the alkoxy group and the silanol group remaining as unreactive groups in the polysiloxane compound of the component (A) can be condensed, and the epoxy group, the oxetane group, the methacryloyl group, and the acryloyl group can be sufficiently cured. In addition, in a case where the polysiloxane compound has an acid-labile group, the remaining photosensitizer can be removed by thermal decomposition.

The heating temperature is preferably 80° C. or higher and 400° C. or lower and more preferably 100° C. or higher and 350° C. or lower. The heating treatment time is generally 1 minute or more and 90 minutes or less and preferably 5 minutes or more and 60 minutes or less. In a case where the heating temperature is lower than 80° C., the acid-labile group and the photosensitizer may be thermally decomposed insufficiently in the condensation and the curing reaction, whereby the chemical liquid resistance and transparency are lowered, and in a case where the heating temperature is higher than 350° C., the thermal decomposition of the polysiloxane compound or the cracking of the film may occur. By this heating treatment, a targeted patterned cured film can be formed on the substrate.

<5> Another Embodiment: A Resin Composition Containing the Component (A1), the Component (A2), and the Component (B)

“Another embodiment” of the present invention is a resin composition containing the following component (A1), component (A2), and component (B).

The component (A1): a polymer containing a constitutional unit represented by Formula (1), but not containing none of a constitutional unit of Formula (2) and a constitutional unit of Formula (3).

The component (A2): a polymer containing at least one of a constitutional unit of Formula (2) and a structural unit of Formula (3), but not containing a constitutional unit represented by Formula (1).

The component (B): a solvent.

As all of the “constitutional unit represented by Formula (1)”, the “constitutional unit of Formula (2)”, and the “structural unit of Formula (3)”, the constitutional units defined so far in the present specification can be mentioned again (in addition, as the preferred substituents, those described as above can be mentioned again).

The difference in the resin composition is that the constitutional unit represented by Formula (1) forms a polymer, that is, the component (A1), and the constitutional unit represented by Formula (2) or Formula (3) forms another polymer, that is, the component (A2). Of these, the polymer of the component (A1) is the known substance according to Patent Document 4 and can be synthesized according to the polymerization method described in the document or the polymerization method described in <1>. On the other hand, the polymer of the component (A2) can also be synthesized according to a conventionally known method by the hydrolysis and polycondensation or the polymerization method described in <1>.

As the “component (B) (solvent)” and the amount thereof, those listed in <1> can be mentioned again.

In the state of the “resin composition”, the resin composition having such a configuration is a blend (a mixture) of different kinds of polymers, unlike the “resin composition containing the component (A) and the component (B)” described <1>. However, in a case where the “resin composition containing the component (A1), the component (A2), and the component (B)” is applied onto a substrate and heat-treated (curing step), a reaction (formation of a siloxane bond) between different molecular silanol groups and a curing reaction of an epoxy group, an acryloyl group, and a methacryloyl group occurs to form a cured film. In this case, the final cured film is “a resin containing the constitutional unit represented by Formula (1), and the constitutional unit of Formula (2) or a constitutional unit of Formula (3)”.

Since even such a polymer (a polysiloxane compound) has the same physical properties as the “resin composition containing the component (A) and the component (B)” described in <1>, the same merit can be also obtained in the present embodiment.

On the other hand, the “resin composition containing the component (A1), the component (A2), and the component (B)” has the advantage that performance adjustment is easy, as compared with the “resin composition containing the component (A) and the component (B)” described in <1>. Specifically, it is possible to easily adjust film properties, alkali developability, and other various physical properties by simply adjusting the blending ratio of the component

(A1) to the component (A2) according to the desired performance (in the “resin composition containing the component (A) and the component (B)”, it is necessary to perform a new polymerization in order to adjust the performance).

The “resin composition containing the component (A1), the component (A2), and the component (B)” also functions as a composition for a positive type resist in a case where the component (C) described above is further added.

As for the meaning of each substituent and the number of substituents in the constitutional units of Formulae (1) to (3) in the component (A1) and the component (A2), those described in the constitutional units of Formulae (1) to (3) in the component (A) can be mentioned again. Regarding the preferred quantity ratio of the component (A1) and the component (A2) (from the viewpoint that they are incorporated into one molecule after the final curing), “the quantity ratio between constitutional units” described in “the resin composition containing the component (A) and the component (B)” described in <1> can be read as “the quantity ratio of the component (A1) to the component (A2)” and can be mentioned again.

As for the kind of solvent suitable as the component (B) and the amount thereof, those described in the “resin composition containing the component (A) and the component (B)” described in <1> can be mentioned again.

In addition, in a case where the component (C) is added to obtain a photosensitive resin composition, as for the description of the kind of component (C) and the amount thereof, those described in the “resin composition containing the component (A) and the component (B)” described in <1> can be mentioned again. As for the patterning method using this photosensitive resin composition, the method and the conditions described in <4> above can be mentioned again.

The “optional component” described in <1> is not prevented from being used in the present embodiment.

The “resin composition containing the component (A) and the component (B)” described in <1> and the “resin composition containing the component (A1), the component (A2), and the component (B)” are not prevented from being used in combination. The mixing ratio of the two is not limited and may be appropriately set by those skilled in the art depending on the intended use, usage environment, and restrictions.

The molecular weight of the polysiloxane compound which is the component (A1) is generally 700 to 100,000, preferably 800 to 10,000, and more preferably 1,000 to 6,000 in terms of the weight-average molecular weight. Basically, the molecular weight can be controlled by adjusting the amount of the catalyst and the temperature of the polymerization reaction.

The molecular weight of the polysiloxane compound which is the component (A2) is preferably in the same range as the molecular weight of the component (A1).

The composition ratio of the polymer which is the component (A) in the resin composition is generally 5% by mass or more and 60% by mass or less and preferably 10% by mass or more and 50% by mass or less. In a case where the composition ratio of the component (A) is appropriately adjusted, it is easy to perform coating and film formation into a uniform resin film having an appropriate film thickness.

<6> Method for Synthesizing a Raw Material Compound of a Constitutional Unit of Formula (1)

Next, methods for producing halosilanes represented by Formula (6) and alkoxysilanes represented by Formula (7), which are the polymerization raw materials for providing the constitutional unit of Formula (1) of the component (A) and the component (A1) among the resin composition, will be described.

The compound represented by Formula (7) is the known compound according to Patent Documents 4 and 5 and may be synthesized according to the description of these documents. However, the inventors have found a more preferred synthetic method for these compounds and have already performed patent application for these findings as Japanese Patent Application No. 2018-35470. The synthetic method therefor has not been disclosed at the time of the present patent application. Therefore, the methods for synthesizing the compounds of Formula (7) and Formula (6), including the undisclosed method, will be described below.

[Method for Synthesizing Halosilanes Represented by Formula (6)

(Step A); in Case where X is Hydrogen]

<Step A>

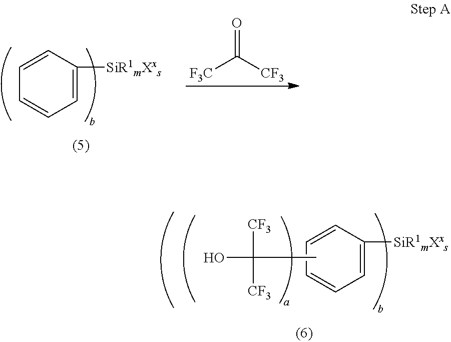

(In the formulae, R¹'s is each independently a hydrogen atom, an alkyl group having 1 to 3 carbon atoms, a phenyl group, a hydroxy group, an alkoxy group having 1 to 3 carbon atoms, or a fluoroalkyl group having 1 to 3 carbon atoms, X^{x} is a halogen atom, a is an integer of 1 to 5, b is an integer of 1 to 3, m is an integer of 0 to 2, and s is an integer of 1 to 3, where b+m+s is 4.)

First, the step A for obtaining an HFIP group-containing aromatic halosilane (6) using an aromatic halosilane (5) as a raw material will be described. Specifically, the aromatic halosilane (5) and a Lewis acid catalyst are collected and mixed in the reaction vessel, hexafluoroacetone is introduced thereto to carry out the reaction, and the reaction product is distilled and purified, whereby the HFIP group-containing aromatic halosilane (6) can be obtained. The step A will be described in detail below.

(Aromatic Halosilane Represented by Formula (5))

An aromatic halosilane used as a raw material is represented by Formula (5) and has a structure in which a phenyl group that reacts with hexafluoroacetone and a halogen atom are directly bonded to a silicon atom.

The aromatic halosilane has a substituent R¹ directly bonded to the silicon atom, and examples of the substituents R¹ include a hydrogen atom, a methyl group, an ethyl group, a propyl group, a butyl group, an isobutyl group, a t-butyl group, a neopentyl group, an octyl group, a cyclohexyl group, a trifluoromethyl group, a perfluorohexyl group, and a perfluorooctyl group. Among them, the substituent R¹ is preferably a methyl group from the viewpoint of the easiness of availability.

Examples of the halogen atom X^{x} in the aromatic halosilane include a fluorine atom, a chlorine atom, a bromine atom, and an iodine atom. X^{x} is preferably a chlorine atom from the viewpoint of the easiness of availability and the stability of the compound.

Specific examples of the aromatic halosilane represented by Formula (5) include the following compounds.

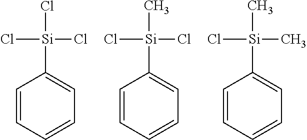

(Lewis Acid Catalyst)

A Lewis acid catalyst used in the present reaction is not particularly limited, and examples thereof include aluminum chloride, iron (III) chloride, zinc chloride, tin (II) chloride, titanium tetrachloride, aluminum bromide, boron trifluoride, a boron trifluoride diethyl ether complex, antimony fluoride, zeolites, and a composite oxide. Among them, aluminum chloride, iron (III) chloride, and boron trifluoride are preferable, and aluminum chloride is most preferable since the reactivity in the present reaction is high. The amount of the Lewis acid catalyst to be used is not particularly limited, but it is preferably 0.01 mol or more and 1.0 mol or less with respect to 1 mol of the aromatic halosilane (1).

(Organic Solvent)

In the present reaction, in a case where the aromatic halosilane as a raw material is liquid, the reaction can be carried out without using an organic solvent. However, in a case where the aromatic halosilane as a raw material is solid or the aromatic halosilane is highly reactive, an organic solvent may be used. The organic solvent is not particularly limited as long as it is a solvent in which an aromatic halosilane is dissolved and does not react with a Lewis acid catalyst or hexafluoroacetone, and pentane, hexane, heptane, octane, acetonitrile, nitromethane, chlorobenzenes, nitrobenzene, and the like can be used. These solvents may be used alone or may be used as a mixture thereof.

(Hexafluoroacetone)

Examples of the kind of hexafluoroacetone to be used in the present reaction include hexafluoroacetone, and a hydrate such hexafluoroacetone trihydrate. Among them, it is preferable to use hexafluoroacetone in the form of gas since the yield decreases in a case where water is mixed during the reaction. The amount of hexafluoroacetone to be used depends on the number of HFIP groups introduced into the aromatic ring, but it is preferably 1 mol equivalent or more and 6 mol equivalents or less with respect to 1 mol of the phenyl group contained in the aromatic halosilane (5) as a raw material. In addition, in a case where three or more HFIP groups are to be introduced into a phenyl group, excessive hexafluoroacetone, a large amount of catalyst, and a long reaction time are required. Therefore, it is preferable that the amount of hexafluoroacetone to be used is 2.5 mol equivalents or less with respect to 1 mol of the phenyl group contained in the aromatic halosilane (5) as a raw material and the number of HFIP groups introduced into the phenyl group is suppressed to 2 or less.

(Reaction Condition)

In a case of synthesizing the HFIP group-containing aromatic halosilane (6), since hexafluoroacetone has a boiling point of −28° C., it is preferable to use a cooling device or a sealed reactor in order to keep hexafluoroacetone in the reaction system and particularly preferable to use a sealed reactor. In a case where the reaction is carried out using a sealed reactor (an autoclave), it is preferable that the aromatic halosilane (5) and the Lewis acid catalyst are placed in the reactor, and then a hexafluoroacetone gas is introduced into the reactor such that the pressure in the reactor does not exceed 0.5 MPa.

The optimum reaction temperature in the present reaction varies greatly depending on the kind of aromatic halosilane (5) to be used as a raw material, but it is preferably carried out in the range of −20° C. to 80° C. In addition, it is desirable that the raw material has the more higher electron density on the aromatic ring and the higher electrophilicity, the reaction is carried out at the lower temperature. In a case where the reaction is carried out at a low temperature as low as possible, the cleavage and opening of the Ph-Si bond during the reaction can be suppressed, and thus the yield of the HFIP group-containing aromatic halosilane (6) is improved.

The reaction time of the reaction is not particularly limited, but it is appropriately selected depending on the amount of HFIP group to be introduced, the temperature, and the amount of catalyst to be used. Specifically, the reaction time is preferably 1 to 24 hours after the introduction of hexafluoroacetone in terms of allowing the reaction to proceed sufficiently.

It is preferable to terminate the reaction after confirming that the raw material has been sufficiently consumed, by a general-purpose analytical means such as gas chromatography. After the completion of the reaction, the Lewis acid catalyst is removed by means such as filtration, extraction, or distillation to obtain the HFIP group-containing aromatic halosilane (6).

[Method for Synthesizing Halosilanes Represented by Formula (6); in Case where X is Acid-Labile Group]

Next, a polysiloxane compound containing a constitutional unit in which X in Formula (1) is an acid-labile group will be described. Specifically, the X group of the HFIP group-containing halosilane represented by Formula (6) is converted from a hydrogen atom into an acid-labile group, and then hydrolysis and polycondensation are carried out to obtain the targeted “polysiloxane compound in which X is an acid-labile group”.

Specific examples of the acid-labile group are as described in <1>.

After hydrolyzing and polycondensing the HFIP group-containing halosilane represented by Formula (6) in which the X group is a hydrogen atom to obtain a polysiloxane compound, the X group may be converted from a hydrogen atom into an acid-labile group.

As described above, those skilled in the art may appropriately determine, depending on the usage environment or restrictions, whether to convert the X group from a hydrogen atom into an acid-labile group at the stage of the halosilane monomer, whether to convert the X group from a hydrogen atom into an acid-labile group after obtaining the polysiloxane compound, or whether to use both in combination.

(HFIP Group-Containing Aromatic Halosilane Represented by Formula (6))

The HFIP group-containing aromatic halosilane obtained by the above method is represented by Formula (6) and has a structure in which the HFIP group and the silicon atom are directly bonded to the aromatic ring.

The HFIP group-containing aromatic halosilane (6) is obtained as a mixture having a plurality of isomers which are different in the number of substitutions of HFIP groups and the position of substitution of HFIP groups. The kinds and the presence ratio of isomers which are different in the number of substitutions of HFIP groups and the position of substitution of HFIP groups differ depending on the structure of the material aromatic halosilane (5) as a raw material and the equivalent of the reacted hexafluoroacetone, but the main isomers have partial structural formulae (1aa) to (1ad).

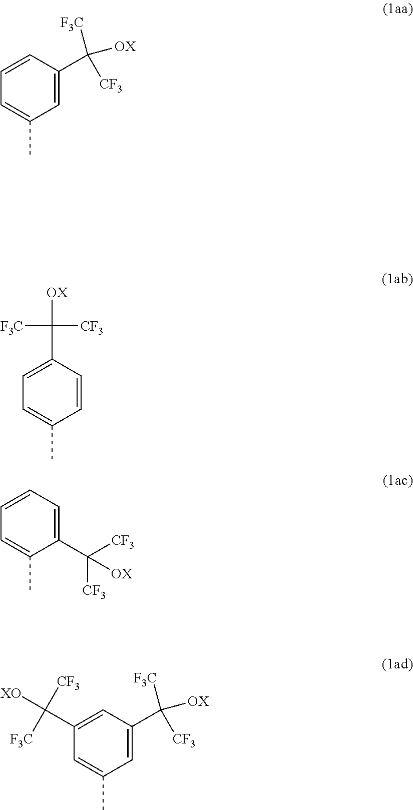

(X is a hydrogen atom or an acid-labile group. Broken lines represent a bond).

[Method for Synthesizing Alkoxysilanes Represented by Formula (7) (Step B); in Case where X is Hydrogen]

<Step B>

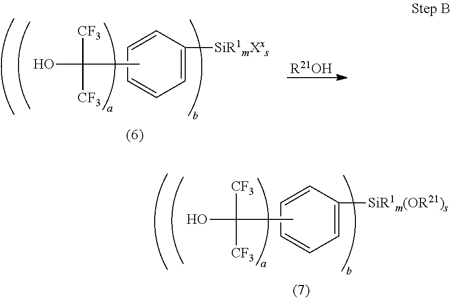

(in the formulae, R¹'s are each independently a hydrogen atom, an alkyl group having 1 to 3 carbon atoms, a phenyl group, a hydroxy group, an alkoxy group having 1 to 3 carbon atoms, or a fluoroalkyl group having 1 to 3 carbon atoms, R²¹'s are each independently a linear alkyl group having 1 to 4 carbon atoms or a branched alkyl group having 3 or 4 carbon atoms, all or a part of hydrogen atoms in the alkyl group may be substituted with fluorine atoms, X^{x} is a halogen atom, a is an integer of 1 to 5, b is an integer of 1 to 3, m is an integer of 0 to 2, and s is an integer of 1 to 3, where b+m+s is 4.)

Next, the step B of obtaining an HFIP group-containing aromatic alkoxysilane (7) using the HFIP group-containing aromatic halosilane (6) which is obtained in the step A as a raw material will be described. Specifically, the halosilane (6) and an alcohol (which refers to R²¹OH described in the step B) are collected and mixed in a reaction vessel, a reaction for converting chlorosilane to an alkoxysilane is carried out, and then the reaction product is distilled and purified, whereby the HFIP group-containing aromatic alkoxysilane (7) can be obtained. The step B will be described in detail below.

(HFIP Group-Containing Aromatic Halosilane Represented by Formula (6), which is Raw Material)

As the HFIP group-containing aromatic halosilane (6) used as a raw material in the step B, the one obtained in the step A can be used. As the HFIP group-containing aromatic halosilane (6), in addition to various isomers separated by precision distillation or the like, the isomer mixture itself can be used without isomer separation.

(Alcohol)

The alcohol is selected depending on the targeted alkoxysilane. Specifically, methanol, ethanol, 1-propanol, 2-propanol, 2-fluoroethanol, 2,2,2-trifluoroethanol, 3-fluoropropanol, 3,3-difluoropropanol, 3,3,3-frifluoropropanol, 2,2,3,3-tetrafluoropropanol, 2,2,3,3,3-pentafluoropropanol, 1,1,1,3,3,3-hexafluoroisopropanol, or the like can be used. Methanol or ethanol is particularly preferable (that is, R²¹ of Formula (7) indicates a methyl group or an ethyl group). In a case where water is mixed at the time of performing the reaction with an alcohol, the hydrolysis reaction and condensation reaction of the HFIP group-containing aromatic halosilane (6) proceed, and the yield of a targeted HFIP group-containing aromatic alkoxysilane (7) is lowered, it is preferable to use an alcohol containing a small amount of water. Specifically, 5% by weight or less is preferable, and 1% by weight or less is more preferable.

(Reaction Condition)

The reaction method for synthesizing the HFIP group-containing aromatic alkoxysilane (7) is not particularly limited, but typical examples thereof are a method in which an alcohol is dropwise added to the HFIP group-containing aromatic halosilane (6) for performing reaction and a method in which the HFIP group-containing aromatic halosilane (6) is dropwise added to an alcohol for performing the reaction.

The reactivity of the alcohol with the HFIP group-containing aromatic halosilane (6) is high, and the halogenosilyl group is rapidly converted to the alkoxysilyl group. However, a hydrogen halide generated during the reaction may be removed for promoting the reaction or suppressing the side reaction. As the method for removing a hydrogen halide, a method in which a generated hydrogen halide gas is removed from the system by heating or bubbling dry nitrogen, in addition to adding a conventionally known trapping agent such as an amine compound, an orthoester, a sodium alkoxide, an epoxy compound, or olefins, is mentioned. These methods may be performed alone or in a combination of two or more thereof.

(Solvent)

In the reaction between the alcohol and the HFIP group-containing aromatic halosilane (6), a solvent may be used for dilution. The solvent to be used is not particularly limited as long as it does not react with the alcohol to used and the HFIP group-containing aromatic halosilane (6), and pentane, hexane, heptane, octane, toluene, xylene, tetrahydrofuran, diethyl ether, dibutyl ether, diisopropyl ether, 1,2-dimethoxyethane, 1,4-dioxane, or the like can be used. These solvents may be used alone or may be used as a mixture thereof.

(Amount of Alcohol)

The amount of alcohol to be used in the step B is not particularly limited, but 1 mol equivalent to 10 mol equivalents is preferable and more preferably 1 mol equivalent to 3 mol equivalent with respect to the Si—X^{x} bond contained in the HFIP group-containing aromatic halosilane (6) since the reaction proceeds efficiently.

(Reaction Temperature)

The addition time of the alcohol or the HFIP group-containing aromatic halosilane (6) is not particularly limited, but it is preferably 10 minutes to 24 hours and more preferably 30 minutes to 6 hours. In addition, the reaction temperature during dropwise addition is not particularly limited and is preferably 0° C. to 80° C.

(Post-Treatment)

The reaction can be completed by performing maturation while continuing stirring after the completion of the dropwise addition. The maturation time is not particularly limited and is preferably 30 minutes to 6 hours since the desired reaction proceeds sufficiently. In addition, the reaction temperature at the time of maturation is preferably the same as the temperature at the time of dropwise addition or higher than the temperature at the time of dropwise addition. It is preferable to terminate the reaction after confirming that the raw material has been sufficiently consumed, by a general-purpose analytical means such as gas chromatography. After the completion of the reaction, purification is performed by means such as filtration, extraction, or distillation to obtain the HFIP group-containing aromatic alkoxysilane (7).

<Another Method which Replaces Step a and Step B>

Among the HFIP group-containing aromatic alkoxysilanes represented by Formula (7), the one represented by Formula (7-1), which contains one aromatic ring (that is, in a case where b in Formula (7) is 1), can be produced by a coupling reaction by using benzene substituted with an HFIP group and a Y group and an alkoxyhydrosilane as raw materials and using a transition metal catalyst such as rhodium, ruthenium, or iridium, according to the producing method disclosed in Japanese Unexamined Patent Publication No. 2014-156461.

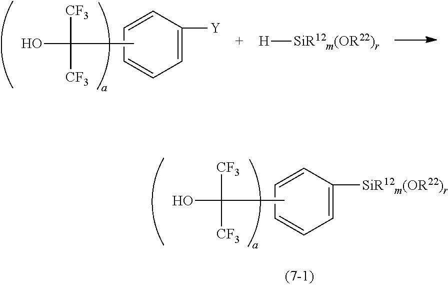

(In the formulae, R¹²'s are each independently a hydrogen atom, an alkyl group having 1 to 3 carbon atoms, a phenyl group, a hydroxy group, an alkoxy group having 1 to 3 carbon atoms, or a fluoroalkyl group having 1 to 3 carbon atoms, R²²'s are each independently a linear alkyl group having 1 to 4 carbon atoms or a branched alkyl group having 3 or 4 carbon atoms, all or a part of hydrogen atoms in the alkyl group may be substituted with fluorine atoms, Y is a chlorine atom, a bromine atom, an iodine atom, an —OSO₂ (p-C₆H₄CH₃) group, or an —OSO₂CF₃ group, a is an integer of 1 to 5, m is an integer of 0 to 2, and r is an integer of 1 to 3, where m+r is 3.)

[Method for Synthesizing Alkoxysilane Represented by Formula (7); in Case where X is an Acid-Labile Group]

Next, a polysiloxane compound containing a constitutional unit in which X in Formula (1) is an acid-labile group will be described. Specifically, the X group of the HFIP group-containing alkoxysilane represented by Formula (7) or Formula (7-1) is converted from a hydrogen atom into an acid-labile group, and then hydrolysis and polycondensation are carried out to obtain the targeted “polysiloxane compound in which X is an acid-labile group”.

In other words, the polysiloxane compound of the component (A) can be obtained by converting a hydrogen atom of a hydroxy group of the alkoxysilane represented by Formula (7) or Formula (7-1), which is described above, into an acid-labile group to obtain an acid labile group-containing alkoxysilane and subsequently hydrolyzing and polycondensing the acid labile group-containing alkoxysilane. Then, a resin composition can be produced by using the polysiloxane compound of the component (A) obtained as described above and the solvent.

In the same manner, the polymer of the component (A1) can be obtained by converting a hydrogen atom of a hydroxy group of the alkoxysilane represented by Formula (7) or Formula (7-1), which is described above, into an acid-labile group to obtain an acid labile group-containing alkoxysilane and subsequently hydrolyzing and polycondensing the acid labile group-containing alkoxysilane. Then, a resin composition can be produced by using the polymer of the component (A1) obtained as described above, the polymer of the component (A2), and the solvent.

Specific examples of the acid-labile group are as described in <1>.

After hydrolyzing and polycondensing the HFIP group-containing alkoxysilane represented by Formula (7) or Formula (7-1) in which the X group is a hydrogen atom to obtain a polysiloxane compound, the X group may be converted from a hydrogen atom into an acid-labile group.

In other words, the polysiloxane compound of the component (A) can be obtained by hydrolyzing and polycondensing the alkoxysilane represented by Formula (7) or Formula (7-1), which is described above, to obtain a polymer and subsequently converting a hydrogen atom of a hydroxy group of the polymer into an acid-labile group. Then, a resin composition can be produced by using the polysiloxane compound of the component (A) obtained as described above and the solvent.

Similarly, the polymer of the component (A1) is obtained by hydrolyzing and polycondensing the alkoxysilane represented by Formula (7) or formula (7-1) to obtain a polymer, and then the hydrogen atom of the hydroxy group in the polymer. It can be obtained by converting an atom into an acid-labile group. Then, a resin composition can be produced by using the polymer of the component (A1) obtained as described above, the polymer of the component (A2), and the solvent.

As described above, those skilled in the art may appropriately determine, depending on the usage environment or restrictions, whether (i) to convert the X group from a hydrogen atom into an acid-labile group at the stage of the alkoxysilane monomer, whether (ii) to convert the X group from a hydrogen atom into an acid-labile group after obtaining the polysiloxane compound, or whether to use both in combination. However, based on the findings of the inventors of the present invention, (i) tends to be preferable from the viewpoints of suppressing the generation of by-products, the light-transmitting property of a cured film to be obtained, and applicability to a photosensitive resin composition. This is presumably because possibilities such as a possibility that the polymerization catalyst (particularly the basic catalyst) is deactivated and thus the polycondensation proceeds smoothly in the case of (i) and a possibility that an unintended by-product is easily generated or a by-product is not easily removed in the case of (ii) are involved.

In any of the above (i) and (ii), as the method for converting an X group from a hydrogen atom into an acid-labile group, a conventionally known method for introducing an acid-labile group into an alcohol compound can be adopted. In Examples described later, a method for introducing an acid-labile group will be specifically described.

It is noted that in any case where any one of the above methods (i) and (ii) is used to obtain the polysiloxane compound which is the component (A), the preferred weight-average molecular weight of the polysiloxane compound is as described above. Similarly, in any case where anyone of the above methods (i) and (ii) is used to obtain the polymer of the component (A1), the preferred weight-average molecular weight of the polymer is as described above.

### Example

Hereinafter, the embodiments of the present invention will be specifically described with reference to Examples, but the present invention is not limited to these Examples.

The analysis of the chlorosilane, alkoxysilane, and polysiloxane compounds obtained in the present examples and the evaluation of the cured film obtained from the resin composition were carried out by the following methods.

[Nuclear Magnetic Resonance (NMR) Measurement]

The ¹H-NMR and ¹⁹F-NMR measurements were performed using a nuclear magnetic resonance apparatus (JNM-ECA400, manufactured by JEOL Ltd.) having a resonance frequency of 400 MHz.

[GC Measurement]

The GC measurement was performed using Shimadzu GC-2010 (trade name) manufactured by Shimadzu Corporation, and the column used for measurement was a capillary column DB1 (60 mm×0.25 mmφ×1 μm).

[Molecular Weight Measurement]

The molecular weight of the polymer was measured by GPC using a gel permeation chromatography (HLC-8320 GPC, manufactured by Tosoh Corporation), and the weight-average molecular weight (Mw) was calculated by the polystyrene standards.

[Thermal Analysis]

The thermogravimetry was performed in air using a thermogravimetry/differential thermal analysis (TG/DTA) apparatus STA7200 manufactured by Hitachi High-Tech Science Corporation, and the temperature at which the weight loss was 5% with respect to the initial weight was defined as the thermal decomposition temperature (Td₅).

[Transmission Spectrum]

The light transmittance was measured using a spectrophotometer U-4100 manufactured by Hitachi High-Tech Corporation and a glass substrate, as a reference, on which a transparent film was not formed.

[Exposure Apparatus]

The photosensitive resin film obtained from the photosensitive resin composition was subjected to the exposure treatment using an exposure apparatus having an apparatus name of MA6, manufactured by SUSS MicroTec SE.

### Synthesis Example 1

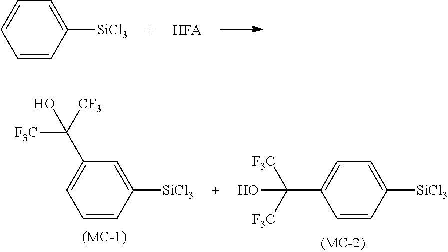

126.92 g (600 mmol) of phenyltrichlorosilane and 8.00 g (60.0 mmol) of aluminum chloride were added in a 300 mL autoclave having a stirrer. Next, after performing nitrogen substitution, the internal temperature was raised to 40° C., 119.81 g (722 mmol) of hexafluoroacetone was added therein over 2 hours, and then stirring was continued for 3 hours.

After the completion of the reaction, the solid content was removed by pressure filtration, and the obtained crude product was distilled under reduced pressure to obtain 215.54 g of a colorless liquid (yield: 95%). When the obtained mixture was analyzed by ¹H-NMR, ¹⁹F-NMR, and GC, it was a mixture of 3-(2-hydroxy-1,1,1,3,3,3-hexafluoroisopropyl)-trichlorosilyl benzene represented by Formula (MC-1) and 4-(2-hydroxy-1,1,1,3,3,3-hexafluoroisopropyl)-trichlorosilyl benzene represented by Formula (MC-2) (GC area %: a total of products having 1, 3 substitutions and 1, 4 substitutions=97.37% (products having 1, 3 substitutions=93.29%, products having 1, 4 substitutions=4.08%)).

In addition, this mixture was subjected to precision distillation to obtain, as a colorless liquid, 3-(2-hydroxy-1,1,1,3,3,3-hexafluoroisopropyl)-trichlorosilyl benzene (GC purity: 98%) represented by Formula (MC-1).

The measurement results of ¹H-NMR and ¹⁹F-NMR of the obtained 3-(2-hydroxy-1,1,1,3,3,3-hexafluoroisopropyl)-trichlorosilyl benzene are shown below.

¹H-NMR (solvent: CDCl₃, TMS): δ 8.17 (s, 1H), 7.96 to 7.89 (m, 2H), 7.64 to 7.60 (dd, J=7.8 Hz, 1H), 3.42 (s, 1H)

¹⁹F-NMR (solvent: CDCl₃, CCl₃F): δ −75.44 (s, 12F).

### Synthesis Example 2

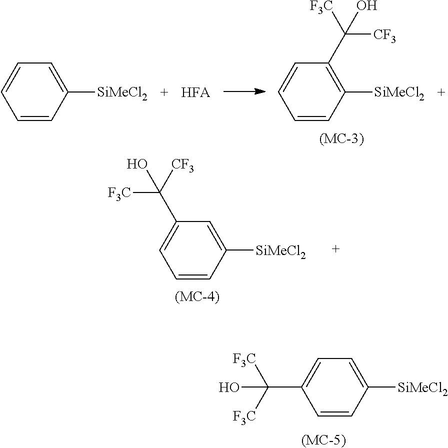

114.68 g (600 mmol) of dichloromethylphenylsilane and 8.00 g (60.0 mmol) of aluminum chloride were added in a 300 mL autoclave having a stirrer. Next, after performing nitrogen substitution, the internal temperature was cooled to 5° C., 99.61 g (600 mmol) of hexafluoroacetone was added therein over 3 hours, and then stirring was continued for 2.5 hours. After the completion of the reaction, the solid content was removed by pressure filtration, and the obtained crude product was distilled under reduced pressure to obtain 178.60 g of a colorless liquid (yield: 83%). When the obtained mixture was analyzed by ¹H-NMR, ¹⁹F-NMR, and GC, it was a mixture of 2-(2-hydroxy-1,1,1,3,3,3-hexafluoroisopropyl)-dichloromethylsily 1 benzene represented by Formula (MC-3), 3-(2-hydroxy-1,1,1,3,3,3-hexafluoroisopropyl)-dichloromethylsily 1 benzene represented by Formula (MC-4), and 4-(2-hydroxy-1,1,1,3,3,3-hexafluoroisopropyl)-dichloromethylsily 1 benzene represented by Formula (MC-5) (GC area %: a total of products having 1, 2 substitutions, products having 1, 3 substitutions, and 1, 4 substitutions=86.34% (products having 1, 2 substitutions=0.57%, products having 1, 3 substitutions=79.33%, products having 1, 4 substitutions=6.44%)).

### Synthesis Example 3

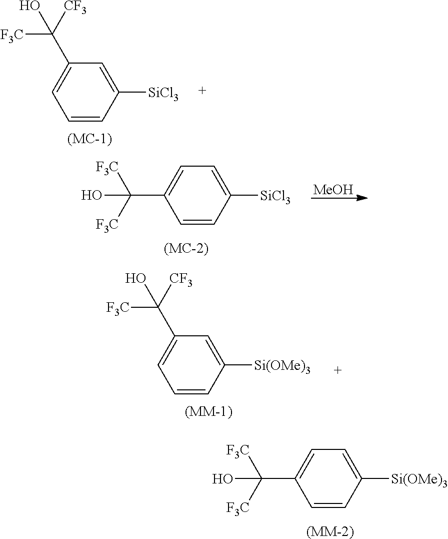

A 200 mL four-necked flask to which a thermometer, a mechanical stirrer, and a Dimroth reflux tube were attached and the inside of which was replaced under a dry nitrogen atmosphere was charged with 113.27 g of the mixture of 3-(2-hydroxy-1,1,1,3,3,3-hexafluoroisopropyl)-trichlorosilyl benzene and 4-(2-hydroxy-1,1,1,3,3,3-hexafluoroisopropyl)-trichlorosilyl benzene (GC area ratio, products having 1 to 3 substitutions:products having 1 to 4 substitutions=96:4), which was synthesized according to the method described in Synthesis Example 1, and the content inside the flask was heated to 60° C. with stirring. Thereafter, while performing nitrogen bubbling, 37.46 g (1,170 mmol) of anhydrous methanol was dropwise added at a rate of 0.5 mL/min using a dropping pump, and an alkoxylation reaction was carried out while removing hydrogen chloride. Stirring was performed for 30 minutes after dropwise addition of the entire amount, then the excess amount of methanol was distilled off using a vacuum pump, and simple distillation was performed, thereby obtaining 87.29 g of a mixture of 3-(2-hydroxy-1,1,1,3,3,3-hexafluoroisopropyl)-trimethoxysilyl benzene represented by Formula (MM-1) and 4-(2-hydroxy-1,1,1,3,3,3-hexafluoroisopropyl)-trimethoxysilyl benzene represented by Formula (MM-2) (GC area %: a total of products having 1, 3 substitutions and 1, 4 substitutions=96.83% (products having 1, 3 substitutions=92.9%, products having 1, 4 substitutions=3.93%)). The yield (the total yield of Synthesis Example 1 and Synthesis Example 4) based on phenyltrichlorosilane was 74%.

In addition, the obtained crude product was subjected to precision distillation to obtain, as a white solid, 3-(2-hydroxy-1,1,1,3,3,3-hexafluoroisopropyl)-trimethoxysilyl benzene (GC purity: 98%) represented by Formula (MM-1).

The measurement results of ¹H-NMR and ¹⁹F-NMR of the obtained 3-(2-hydroxy-1,1,1,3,3,3-hexafluoroisopropyl)-trimethoxysilyl benzene are shown below.

¹H-NMR (solvent: CDCl₃, TMS): δ 7.98 (s, 1H), 7.82 to 7.71 (m, 2H), 7.52 to 7.45 (dd, J=7.8 Hz, 1H), 3.61 (s, 9H), ¹⁹F-NMR (solvent: CDCl₃, CCl₃F): δ −75.33 (s, 12F).

### Synthesis Example 4

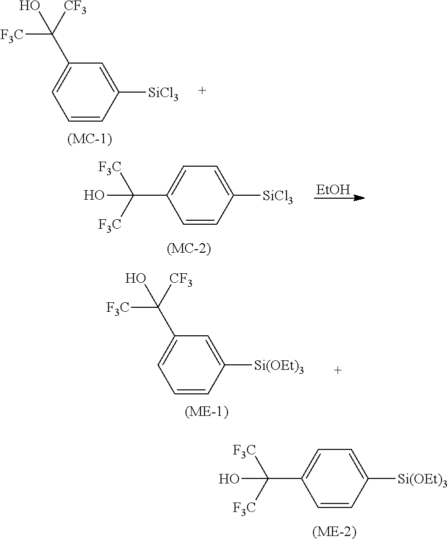

A 300 mL four-necked flask to which a thermometer, a mechanical stirrer, and a Dimroth reflux tube were attached and the inside of which was replaced under a dry nitrogen atmosphere was charged with 188.80 g of the mixture of 3-(2-hydroxy-1,1,1,3,3,3-hexafluoroisopropyl)-trichlorosilyl benzene and 4-(2-hydroxy-1,1,1,3,3,3-hexafluoroisopropyl)-trichlorosilyl benzene (GC area ratio, products having 1, 3 substitutions:products having 1, 4 substitutions=96:4), which was synthesized according to the method described in Synthesis Example 1, and the content inside the flask was heated to 60° C. with stirring. Thereafter, while performing nitrogen bubbling, 89.80 g (1,950 mmol) of anhydrous ethanol was dropwise added at a rate of 1 mL/min using a dropping pump, and an alkoxylation reaction was carried out while removing hydrogen chloride. Stirring was performed for 30 minutes after dropwise addition of the entire amount, and then the excess amount of ethanol was distilled off using a vacuum pump. The amount of unreacted chlorosilane compound was calculated by performing gas chromatography measurement of this reaction product.

Subsequently, 3.39 g (10.0 mmol) of a 20% by mass sodium ethoxide ethanol solution of 1.2 equivalents with respect to the number of moles of chloro groups of the unreacted chlorosilane was added to the above reaction product, and the reaction was carried out for 30 minutes. The excess amount of ethanol was distilled off using a vacuum pump, and then simple distillation was performed, thereby obtaining 159.58 g of a mixture of 3-(2-hydroxy-1,1,1,3,3,3-hexafluoroisopropyl)-triethoxysilyl benzene represented by Formula (ME-1) and 4-(2-hydroxy-1,1,1,3,3,3-hexafluoroisopropyl)-triethoxysilyl benzene represented by Formula (ME-2) (GC area %: a total of products having 1, 3 substitutions and 1, 4 substitutions=95.26% (products having 1, 3 substitutions=91.58%, products having 1, 4 substitutions=3.68%)). The yield (the total yield of Synthesis Example 1 and Synthesis Example 4) based on phenyltrichlorosilane was 75%.

In addition, the obtained crude product was subjected to precision distillation to obtain, as a colorless transparent liquid, 3-(2-hydroxy-1,1,1,3,3,3-hexafluoroisopropyl)-trietoxysilyl benzene (GC purity: 98%) represented by Formula (ME-1) and 4-(2-hydroxy-1,1,1,3,3,3-hexafluoroisopropyl)-triethoxysilyl benzene (GC purity: 95%) represented by Formula (ME-2).

The measurement results of ¹H-NMR and ¹⁹F-NMR of the obtained 3-(2-hydroxy-1,1,1,3,3,3-hexafluoroisopropyl)-triethoxysilyl benzene are shown below.

¹H-NMR (solvent: CDCl₃, TMS): δ 8.00 (s, 1H), 7.79 to 7.76 (m, 2H), 7.47 (t, J=7.8 Hz, 1H), 3.87 (q, J=6.9 Hz, 6H), 3.61 (s, 1H), 1.23 (t, J=7.2 Hz, 9H)

¹⁹F-NMR (solvent: CDCl₃, CCl₃F): δ −75.99 (s, 6F) The measurement results of ¹H-NMR and ¹⁹F-NMR of the obtained 4-(2-hydroxy-1,1,1,3,3,3-hexafluoroisopropyl)-triethoxysilyl benzene are shown below.

¹H-NMR (solvent: CDCl₃, TMS): δ 7.74 (4H, dd, J=18.6, 8.3 Hz), 3.89 (6H, q, J=7.0 Hz), 3.57 (1H, s), 1.26 (9H, t, J=7.0 Hz)

¹⁹F-NMR (solvent: CDCl₃, CCl₃F): δ −75.94 (s, 6F).

### Synthesis Example 5

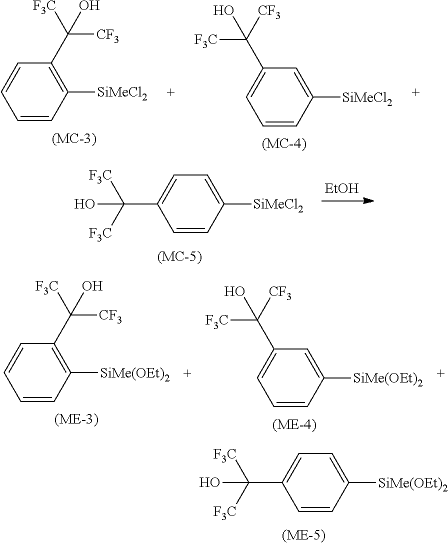

A 300 mL four-necked flask to which a thermometer, a mechanical stirrer, and a Dimroth reflux tube were attached and the inside of which was replaced under a dry nitrogen atmosphere was charged with 178.60 g of the mixture of 2-(2-hydroxy-1,1,1,3,3,3-hexafluoroisopropyl)-dichloromethylsily 1 benzene, 3-(2-hydroxy-1,1,1,3,3,3-hexafluoroisopropyl)-dichloromethylsily 1 benzene, and 4-(2-hydroxy-1,1,1,3,3,3-hexafluoroisopropyl)-diichloromethylsil yl benzene (GC area ratio, products having 1, 2 substitutions:products having 1, 3 substitutions:products having 1, 4 substitutions=1:92:7), which was synthesized according to the method described in Synthesis Example 2, and the content inside the flask was heated to 40° C. with stirring. Thereafter, while performing nitrogen bubbling, 81.80 g (1,400 mmol) of anhydrous ethanol was dropwise added at a rate of 1 mL/min using a dropping pump, and an alkoxylation reaction was carried out while removing hydrogen chloride. Stirring was performed for 30 minutes after dropwise addition of the entire amount, and then the excess amount of ethanol was distilled off using a vacuum pump. The amount of unreacted chlorosilane compound was calculated by performing gas chromatography measurement of this reaction product.

Subsequently, 5.95 g (17.5 mmol) of a 20% by mass sodium ethoxide ethanol solution of 1.2 equivalents with respect to the number of moles of chloro groups of the unreacted chlorosilane was added to the above reaction product, and the reaction was carried out for 30 minutes. Excess ethanol was distilled off using a vacuum pump, and then simple distillation was performed to obtain 155.90 g of a mixture of 2-(2-hydroxy-1,1,1,3,3,3-hexafluoroisopropyl)-diethoxysilyl benzene represented by Formula (ME-3), 3-(2-hydroxy-1,1,1,3,3,3-hexafluoroisopropyl)-diethoxylsilyl benzene represented by Formula (ME-4), and 4-(2-hydroxy-1,1,1,3,3,3-hexafluoroisopropyl)-diethoxylsilyl benzene represented by Formula (ME-5) (GC area %: a total of products having 1,2 substitutions, products having 1, 3 substitutions, and 1, 4 substitutions=88.41% (products having 1, 2 substitutions=0.60%, products having 1, 3 substitutions=83.50%, products having 1, 4 substitutions=4.31%)). The yield (the total yield of Synthesis Example 2 and Synthesis Example 5) based on dichloromethylphenylsilane was 69%.

In addition, the obtained crude product was subjected to precision distillation (number of distillation stages: 10 stages, reflux ratio: 10, pressure: 0.3 kPa, temperature: 150° C.), to obtain, as a colorless transparent liquid, 3-(2-Hydroxy-1,1,1,3,3,3-hexafluoroisopropyl)-diethoxymethylsily 1 benzene (GC purity: 98%) represented by Formula (ME-4).

The measurement results of ¹H-NMR and ¹⁹F-NMR of the obtained 3-(2-hydroxy-1,1,1,3,3,3-hexafluoroisopropyl)-diethoxymethylsily 1 benzene are shown below.

¹H-NMR (solvent: CDCl₃, TMS): δ 7.96 (s, 1H), 7.76 to 7.73 (m, 2H), 7.47 (t, J=7.8 Hz, 1H), 3.86 to 3.75 (m, 6H), 3.49 (s, 1H), 1.23 (t, J=7.2 Hz, 6H), 0.37 (s, 3H)

¹⁹F-NMR (solvent: CDCl₃, CCl₃F): δ −75.96 (s, 6F).

### Synthesis Example 6

3,5-di (2-hydroxy-1,1,1,3,3,3-hexafluoroisopropyl)-triethoxy silyl benzene represented by Formula (ME-1-1) was obtained according to the description of Example 1 of Patent Document 4 (Japanese Unexamined Patent Publication No. 2014-156461).

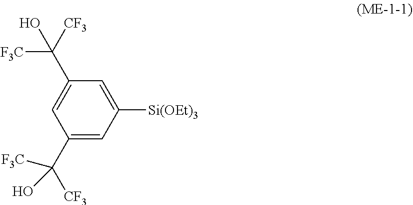

### Example 1

18.21 g (45 mmol) of ME-1 obtained in Synthesis Example 4, 1.23 g (5 mmol) of 2-(3,4-epoxycyclohexylethyltrimethoxysilane) (KBM-303 manufactured by Shin-Etsu Chemical Co., Ltd.), 2.84 g (158 mmol) of water, and 0.15 g (2.5 mmol) of acetic acid were added in a 50 mL flask, and the resultant mixture was stirred at 100° C. for 2 hours. Thereafter, 10 g of propylene glycol monomethyl ether acetate was added therein, and a fraction of distillation was removed with a Dean-Stark distillation apparatus at 130° C. for 2 hours. Thereafter, after cooling to room temperature, propylene glycol monomethyl ether acetate was added therein to obtain a solution composition (P-1) having a solid content concentration of 25% by mass. The result of GPC measurement was Mw=1,920.

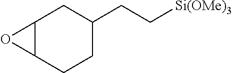

### 2-(3,4-epoxycyclohexylethyltrimethoxysilane)

### Example 2

9.14 g (22.5 mmol) of ME-1 obtained in Synthesis Example 4, 5.41 g (22.5 mmol) of phenyltriethoxysilane, 1.23 g (5 mmol) of 2-(3,4-epoxycyclohexylethyltrimethoxysilane) (KBM-303 manufactured by Shin-Etsu Chemical Co., Ltd.), 2.84 g (158 mmol) of water, and 0.15 g (2.5 mmol) of acetic acid were added in a 50 mL flask, and the resultant mixture was stirred at 100° C. for 2 hours. Thereafter, a solution composition (P-2) having a solid content concentration of 25% by mass was obtained by the same method as in Example 1. The result of GPC measurement was Mw=1,730.

### Example 3

9.14 g (22.5 mmol) of ME-1 obtained in Synthesis Example 4, 5.41 g (22.5 mmol) of phenyltriethoxysilane, 3.73 g of ethyl polysilicate (Silicate 40, manufactured by Tama Chemicals Co., Ltd.), 2.84 g (158 mmol) of water, and 0.15 g (2.5 mmol) of acetic acid were added in a 50 mL flask, and the resultant mixture was stirred at 100° C. for 2 hours. Thereafter, a solution composition (P-3) having a solid content concentration of 25% by mass was obtained by the same method as in Example 1. The result of GPC measurement was Mw=2,080.

### Example 4

9.14 g (22.5 mmol) of ME-1 obtained in Synthesis Example 4, 5.41 g (22.5 mmol) of phenyltriethoxysilane, 1.17 g (5 mmol) of 3-acryloxypropyltrimethoxysilane (KBM-5103 manufactured by Shin-Etsu Chemical Co., Ltd.), 2.84 g (158 mmol) of water, and 0.15 g (2.5 mmol) of acetic acid were added in a 50 mL flask, and the resultant mixture was stirred at 100° C. for 2 hours. Thereafter, a solution composition (P-4) having a solid content concentration of 25% by mass was obtained by the same method as in Example 1. The result of GPC measurement was Mw=2,940.

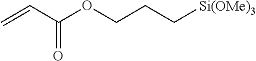

### 3-acryloxypropyltrimethoxysilane

### Example 5

18.21 g (45 mmol) of ME-2 obtained in Synthesis Example 4, 1.18 g (5 mmol) of 3-glycidoxypropyltrimethoxysilane (KBM-403 manufactured by Shin-Etsu Chemical Co., Ltd.), 2.84 g (158 mmol) of water, and 0.15 g (2.5 mmol) of acetic acid were added in a 50 mL flask, and the resultant mixture was stirred at 100° C. for 2 hours. Thereafter, a solution composition (P-5) having a solid content concentration of 25% by mass was obtained by the same method as in Example 1. The result of GPC measurement was Mw=2,200.

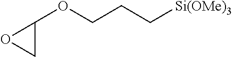

### 3-glycidoxypropyltrimethoxysilane

### Example 6

16.19 g (40 mmol) of ME-2 obtained in Synthesis Example 4, 3.73 g of ethyl polysilicate (Silicate 40, manufactured by Tama Chemicals Co., Ltd.), 2.84 g (158 mmol) of water, and 0.15 g (2.5 mmol) of acetic acid were added in a 50 mL flask, and the resultant mixture was stirred at 100° C. for 2 hours. Thereafter, a solution composition (P-6) having a solid content concentration of 25% by mass was obtained by the same method as in Example 1. The result of GPC measurement was Mw=8,080.

### Example 7

9.14 g (22.5 mmol) of ME-2 obtained in Synthesis Example 4, 5.41 g (22.5 mmol) of phenyltriethoxysilane, 1.24 g (5 mmol) of 3-methacryloxypropyltrimethoxysilane (KBM-503 manufactured by Shin-Etsu Chemical Co., Ltd.), 2.84 g (158 mmol) of water, and 0.15 g (2.5 mmol) of acetic acid were added in a 50 mL flask, and the resultant mixture was stirred at 100° C. for 2 hours. Thereafter, a solution composition (P-7) having a solid content concentration of 25% by mass was obtained by the same method as in Example 1. The result of GPC measurement was Mw=2,620.

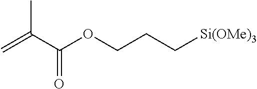

### 3-methacryloxypropyltriethoxysilane

### Example 8

8.47 g (22.5 mmol) of ME-4 obtained in Synthesis Example 5, 5.41 g (22.5 mmol) of phenyltriethoxysilane, 1.23 g (5 mmol) of 2-(3,4-epoxycyclohexylethyltrimethoxysilane) (KBM-303 manufactured by Shin-Etsu Chemical Co., Ltd.), 2.84 g (158 mmol) of water, and 0.15 g (2.5 mmol) of acetic acid were added in a 50 mL flask, and the resultant mixture was stirred at 100° C. for 2 hours. Thereafter, a solution composition (P-8) having a solid content concentration of 25% by mass was obtained by the same method as in Example 1. The result of GPC measurement was Mw=1,910.

### Example 9

8.47 g (22.5 mmol) of ME-4 obtained in Synthesis Example 5, 5.41 g (22.5 mmol) of phenyltriethoxysilane, 1.82 g of ethyl polysilicate (Silicate 40, manufactured by Tama Chemicals Co., Ltd.), 2.84 g (158 mmol) of water, and 0.15 g (2.5 mmol) of acetic acid were added in a 50 mL flask, and the resultant mixture was stirred at 100° C. for 2 hours. Thereafter, a solution composition (P-9) having a solid content concentration of 25% by mass was obtained by the same method as in Example 1. The result of GPC measurement was Mw=2,350.

### Example 10

15.10 g (40 mmol) of MC-1 obtained in Synthesis Example 1, 7.46 g of ethyl polysilicate (Silicate 40, manufactured by Tama Chemicals Co., Ltd.), and 0.15 g (2.5 mmol) of acetic acid were added in a 50 mL flask, and the resultant mixture was stirred at 100° C. for 2 hours. Thereafter, a solution composition (P-10) having a solid content concentration of 25% by mass was obtained by the same method as in Example 1. The result of GPC measurement was Mw=9,100.

### Example 11

16.40 g (45 mmol) of MM-1 obtained in Synthesis Example 3, 1.23 g (5 mmol) of 2-(3,4-epoxycyclohexylethyltrimethoxysilane) (KBM-303 manufactured by Shin-Etsu Chemical Co., Ltd.), 2.84 g (158 mmol) of water, and 0.15 g (2.5 mmol) of acetic acid were added in a 50 mL flask, and the resultant mixture was stirred at 100° C. for 2 hours. Thereafter, a solution composition (P-11) having a solid content concentration of 25% by mass was obtained by the same method as in Example 1. The result of GPC measurement was Mw=1,680.

### Example 12

25.64 g (45 mmol) of ME-1-1 obtained in Synthesis Example 6, 1.23 g (5 mmol) of 2-(3,4-epoxycyclohexylethyltrimethoxysilane) (KBM-303 manufactured by Shin-Etsu Chemical Co., Ltd.), 2.84 g (158 mmol) of water, and 0.15 g (2.5 mmol) of acetic acid were added in a 50 mL flask, and the resultant mixture was stirred at 100° C. for 2 hours. Thereafter, a solution composition (P-12) having a solid content concentration of 25% by mass was obtained by the same method as in Example 1. The result of GPC measurement was Mw=2,880.

### Example 13

12.82 g (22.5 mmol) of ME-1-1 obtained in Synthesis Example 6, 5.41 g (22.5 mmol) of phenyltriethoxysilane, 1.18 g (5 mmol) of 3-glycidoxypropyltrimethoxysilane) (KBM-403 manufactured by Shin-Etsu Chemical Co., Ltd.), 2.84 g (158 mmol) of water, and 0.15 g (2.5 mmol) of acetic acid were added in a 50 mL flask, and the resultant mixture was stirred at 100° C. for 2 hours. Thereafter, a solution composition (P-13) having a solid content concentration of 25% by mass was obtained by the same method as in Example 1. The result of GPC measurement was Mw=2,230.

### Example 14

18.21 g (45 mmol) of ME-1 obtained in Synthesis Example 4, 1.23 g (5 mmol) of 2-(3,4-epoxycyclohexylethyltrimethoxysilane) (KBM-303 manufactured by Shin-Etsu Chemical Co., Ltd.), 2.84 g (158 mmol) of water, and 0.15 g (2.5 mmol) of acetic acid were added in a 50 mL flask, and the resultant mixture was stirred at 100° C. for 2 hours.

Thereafter, 10 g of toluene was added therein, and a fraction of distillation was removed with a Dean-Stark distillation apparatus at 150° C. for 4 hours. Thereafter, after cooling to room temperature, 12.28 g (56.3 mmol) of di-tert-butyl dicarbonate, 0.55 g (0.45 mmol) of N,N-dimethyl-4-aminopyridine, and 30 mL of pyridine were added therein, and stirring was performed at 100° C. for 15 hours. After stirring, pyridine and the di-tert-butyl dicarbonate excessively added were distilled off. Thereafter, after cooling to room temperature, propylene glycol monomethyl ether acetate was added therein to obtain a solution composition (P-14) having a solid content concentration of 25% by mass. The result of GPC measurement was Mw=2,120.

### Example 15

9.14 g (22.5 mmol) of ME-1 obtained in Synthesis Example 4, 5.41 g (22.5 mmol) of phenyltriethoxysilane, 1.18 g (5 mmol) of 3-glycidoxypropyltrimethoxysilane) (KBM-403 manufactured by Shin-Etsu Chemical Co., Ltd.), 2.84 g (158 mmol) of water, and 0.15 g (2.5 mmol) of acetic acid were added in a 50 mL flask, and the resultant mixture was stirred at 100° C. for 2 hours. Thereafter, 10 g of toluene was added therein, and a fraction of distillation was removed with a Dean-Stark distillation apparatus at 150° C. for 4 hours.

Thereafter, after cooling to room temperature, 24.5 g (112.6 mmol) of di-tert-butyl dicarbonate, 1.10 g (0.90 mmol) of N,N-dimethyl-4-aminopyridine, and 40 mL of pyridine were added therein, and stirring was performed at 100° C. for 15 hours. After stirring, pyridine and excess di-tert-butyl dicarbonate were distilled off. Thereafter, after cooling to room temperature, propylene glycol monomethyl ether acetate was added therein to obtain a solution composition (P-15) having a solid content concentration of 25% by mass. The result of GPC measurement was Mw=2,350.

### Example 16

1 part by weight of 2,4,6-trimethylbenzoyl-diphenyl-phosphine oxide (LUCRIN TPO manufactured by BASF Japan Ltd.) and 0.3 parts by weight of 4,4′-bis(diethylamino)benzophenone were added with respect to 100 parts by weight of the solution composition (P-4) obtained in Example 4, thereby obtaining a solution composition P-16.

### Example 17

2.03 g (5 mmol) of ME-1 obtained in Synthesis Example 4, 9.62 g (40 mmol) of phenyltriethoxysilane, 1.23 g (5 mmol) of 2-(3,4-epoxycyclohexylethyltrimethoxysilane) (KBM-303 manufactured by Shin-Etsu Chemical Co., Ltd.), 2.84 g (158 mmol) of water, and 0.15 g (2.5 mmol) of acetic acid were added in a 50 mL flask, and the resultant mixture was stirred at 100° C. for 2 hours. Thereafter, a solution composition (P-17) having a solid content concentration of 25% by mass was obtained by the same method as in Example 1. The result of GPC measurement was Mw=2,150.

### Example 18

2.03 g (5 mmol) of ME-1 obtained in Synthesis Example 4, 2.40 g (10 mmol) of phenyltriethoxysilane, 1.23 g (5 mmol) of 2-(3,4-epoxycyclohexylethyltrimethoxysilane) (KBM-303 manufactured by Shin-Etsu Chemical Co., Ltd.), 7.02 g (30 mmol) of 3-acryloxypropyltrimethoxysilane (KBM-5103 manufactured by Shin-Etsu Chemical Co., Ltd.), 2.84 g (158 mmol) of water, and 0.15 g (2.5 mmol) of acetic acid were added in a 50 mL flask, and the resultant mixture was stirred at 100° C. for 2 hours. Thereafter, a solution composition (P-18) having a solid content concentration of 25% by mass was obtained by the same method as in Example 1. The result of GPC measurement was Mw=2,370.

### Example 19

2.03 g (5 mmol) of ME-1 obtained in Synthesis Example 4, 8.42 g (35 mmol) of phenyltriethoxysilane, 1.23 g (5 mmol) of 2-(3,4-epoxycyclohexylethyltrimethoxysilane) (KBM-303 manufactured by Shin-Etsu Chemical Co., Ltd.), 0.75 g of ethyl polysilicate (Silicate 40, manufactured by Tama Chemicals Co., Ltd.), 2.84 g (158 mmol) of water, and 0.15 g (2.5 mmol) of acetic acid were added in a 50 mL flask, and the resultant mixture was stirred at 100° C. for 2 hours. Thereafter, a solution composition (P-19) having a solid content concentration of 25% by mass was obtained by the same method as in Example 1. The result of GPC measurement was Mw=3,100.

### Example 20

4.06 g (10 mmol) of ME-1 obtained in Synthesis Example 4, 8.42 g (35 mmol) of phenyltriethoxysilane, 1.18 g (5 mmol) of 3-glycidoxypropyltrimethoxysilane) (KBM-403 manufactured by Shin-Etsu Chemical Co., Ltd.), 2.84 g (158 mmol) of water, and 0.15 g (2.5 mmol) of acetic acid were added in a 50 mL flask, and the resultant mixture was stirred at 100° C. for 2 hours. Thereafter, a solution composition (P-20) having a solid content concentration of 25% by mass was obtained by the same method as in Example 14. The result of GPC measurement was Mw=2,410.

### Example 21

4.06 g (10 mmol) of ME-1 obtained in Synthesis Example 4, 8.42 g (35 mmol) of phenyltriethoxysilane, 1.18 g (5 mmol) of 3-glycidoxypropyltrimethoxysilane) (KBM-403 manufactured by Shin-Etsu Chemical Co., Ltd.), 2.84 g (158 mmol) of water, and 0.15 g (2.5 mmol) of acetic acid were added in a 50 mL flask, and the resultant mixture was stirred at 100° C. for 2 hours.

Thereafter, 10 g of toluene was added therein, and a fraction of distillation was removed with a Dean-Stark distillation apparatus at 150° C. for 4 hours. Thereafter, after cooling to room temperature, 10.9 g (50.0 mmol) of di-tert-butyl dicarbonate, 0.48 g (0.40 mmol) of N,N-dimethyl-4-aminopyridine, and 20 mL of pyridine were added therein, and stirring was performed at 100° C. for 15 hours. After stirring, pyridine and the di-tert-butyl dicarbonate excessively added were distilled off. Thereafter, after cooling to room temperature, propylene glycol monomethyl ether acetate was added therein to obtain a solution composition (P-21) having a solid content concentration of 25% by mass. The result of GPC measurement was Mw=3,050.

### Example 22

1.02 g (2.5 mmol) of ME-1 obtained in Synthesis Example 4, 10.22 g (42.5 mmol) of phenyltriethoxysilane, 1.23 g (5 mmol) of 2-(3,4-epoxycyclohexylethyltrimethoxysilane) (KBM-303 manufactured by Shin-Etsu Chemical Co., Ltd.), 2.84 g (158 mmol) of water, and 0.15 g (2.5 mmol) of acetic acid were added in a 50 mL flask, and the resultant mixture was stirred at 100° C. for 2 hours. Thereafter, a solution composition (P-22) having a solid content concentration of 25% by mass was obtained by the same method as in Example 1. The result of GPC measurement was Mw=2,280.

### Example 23

1.02 g (2.5 mmol) of ME-1 obtained in Synthesis Example 4, 10.82 g (45 mmol) of phenyltriethoxysilane, 0.62 g (2.5 mmol) of 2-(3,4-epoxycyclohexylethyltrimethoxysilane) (KBM-303 manufactured by Shin-Etsu Chemical Co., Ltd.), 2.84 g (158 mmol) of water, and 0.15 g (2.5 mmol) of acetic acid were added in a 50 mL flask, and the resultant mixture was stirred at 100° C. for 2 hours. Thereafter, a solution composition (P-23) having a solid content concentration of 25% by mass was obtained by the same method as in Example 1. The result of GPC measurement was Mw=2,060.

### Comparative Example 1

20.23 g (50 mmol) of ME-1 obtained in Synthesis Example 4, 2.84 g (158 mmol) of water, and 0.15 g (2.5 mmol) of acetic acid were added in a 50 mL flask, and the resultant mixture was stirred at 100° C. for 2 hours. Thereafter, 10.0 g of a solution composition (CP-1) having a solid content concentration of 25% by mass was obtained by the same method as in Example 1. The result of GPC measurement was Mw=1,850.

### Comparative Example 2

10.12 g (25 mmol) of ME-1 obtained in Synthesis Example 4, 6.01 g (25 mmol) of phenyltriethoxysilane, 2.84 g (158 mmol) of water, and 0.15 g (2.5 mmol) of acetic acid were added in a 50 mL flask, and the resultant mixture was stirred at 100° C. for 2 hours. Thereafter, 10.0 g of a solution composition (CP-2) having a solid content concentration of 25% by mass was obtained by the same method as in Example 1. The result of GPC measurement was Mw=1,850.

### Comparative Example 3

1.01 g (2.5 mmol) of ME-1 obtained in Synthesis Example 4, 10.82 g (45 mmol) of phenyltriethoxysilane, 2.84 g (158 mmol) of water, and 0.15 g (2.5 mmol) of acetic acid were added in a 50 mL flask, and the resultant mixture was stirred at 100° C. for 2 hours. Thereafter, 10.0 g of a solution composition (CP-3) having a solid content concentration of 25% by mass was obtained by the same method as in Example 1. The result of GPC measurement was Mw=2,050.

[Production Cured Film]

A 4-inch silicon wafer was spin-coated with each of the solution compositions obtained in Examples 1 to 13, 16 to 20, P-1 to P-13, P-16 to 20, P-22, and P-23, and solution compositions CP-1 to 3 obtained in Comparative Examples 1 and 2 at 1,500 rpm for 1 minute, and then heat-treated at 100° C. for 1 minute, whereby a resin film was obtained.

Resin films obtained from the solution compositions of P-1 to P-13, P-17 to P-20, P-22, P-23, and CP-1 to 3 were heat-treated at 250° C. for 1 hour to obtain cured films having a film thickness of 1.5 to 3.0 μm.

The resin film obtained from the solution composition of P-16 was subjected to an exposure treatment under the condition of 200 mJ/cm² and then heat-treated at 250° C. for 1 hour to obtain a cured film having a film thickness of 1.7 μm.

The following thermal decomposition temperature, solvent resistance, acid resistance, and alkali resistance were evaluated for the cured films obtained as described above.

[Evaluation of Thermal Decomposition Temperature]

The cured film obtained above was scraped off with a spatula, and the thermal decomposition temperature (Td₅: 5% weight loss temperature) was measured. The results are shown in Table 1.

[Evaluation of Solvent Resistance]

Each of the cured films obtained above was immersed in PGMEA and NMP at room temperature for 1 minute. The film after the immersion treatment was visually observed. The results are shown in Table 1.

[Evaluation of Resistance to Acid]

Each of the cured films obtained above was immersed in a solution of a mixture of concentrated hydrochloric acid: 98% nitric acid:water (50:7.5:42.5, in terms of mass ratio) at room temperature for 1 minute. The film after the immersion treatment was visually observed. The results are shown in Table 2.

[Evaluation of Resistance to Alkali]

Each of the cured films obtained above was immersed in a solution of a mixture of dimethyl sulfoxide:monoethanol amine:water (1:1:2, in terms of mass ratio) at room temperature for 1 minute. The film after the immersion treatment was visually observed. The results are shown in Table 2.

[Evaluation of Transparency]

The above-described resin films and cured films were produced in the same manner except that a 4-inch glass substrate was used instead of the 4-inch silicon wafer, whereby cured films having a film thickness of 1.5 to 3.0 μm, which were produced on the 4-inch glass substrate were obtained from solution compositions P-1 to P-13, P-16 to P-20, P-22, and P-23, and solution compositions CP-1 to 3, which were respectively obtained in Examples 1 to 13, 16 to 20, 22, and 23, and Comparative Examples CP-1 to 3. The transmission spectrum of the cured film was measured, and the transmittance at a wavelength of 400 nm is shown in Table 1 in terms of a film thickness of 2 μm.

TABLE 1

| | | Td₅ | Trans- | | |
|---|---|---|---|---|---|
| | Solution | [unit: | mittance | Solvent resistance | |
| | composition | ° C.] | [unit: %] | PGMEA | NMP |
| Example 1 | P-1 | 370 | >95 | B | B |
| Example 2 | P-2 | 400 | >95 | A | A |
| Example 3 | P-3 | 395 | >95 | A | A |
| Example 4 | P-4 | 390 | >95 | B | B |
| Example 5 | P-5 | 375 | >95 | B | B |
| Example 6 | P-6 | 380 | >95 | A | A |
| Example 7 | P-7 | 380 | >95 | B | B |
| Example 8 | P-8 | 390 | >95 | A | B |
| Example 9 | P-9 | 395 | >95 | A | A |
| Example 10 | P-10 | 390 | >95 | A | A |
| Example 11 | P-11 | 375 | >95 | B | B |
| Example 12 | P-12 | 385 | >95 | B | B |
| Example 13 | P-13 | 410 | >95 | A | A |
| Example 16 | P-16 | 395 | >95 | B | B |
| Example 17 | P-17 | 430 | >95 | A | A |
| Example 18 | P-18 | 380 | >95 | A | A |
| Example 19 | P-19 | 435 | >95 | A | A |
| Example 20 | P-20 | 415 | >95 | A | A |
| Example 22 | P-22 | 425 | >95 | A | A |
| Example 23 | P-23 | 420 | >95 | A | A |
| Comparative | CP-1 | 360 | >95 | X | X |
| Example 1 | | | | | |
| Comparative | CP-2 | 400 | >95 | X | X |
| Example 2 | | | | | |
| Comparative | CP-3 | 430 | >95 | X | X |
| Example 3 | | | | | |

Resistance to PGMEA:

A (Very good): unevenness is not observed, or the proportion thereof is less than 1% of the total area even in the case of being observed.

B (Good): at least one of peeling and streaking is observed, but the proportion thereof is 1% or more and less than 10% of the total area.

X (Bad): The film is dissolved.

Resistance to NMP:

A (Very good): unevenness is not observed, or the proportion thereof is less than 1% of the total area even in the case of being observed.

B (Good): at least one of peeling and streaking is observed, but the proportion thereof is 1% or more and less than 10% of the total area.

X (Bad): The film is dissolved.

TABLE 2

| | Solution | Solvent resistance | |
|---|---|---|---|
| | composition | Acid | Alkali |
| Example 1 | P-1 | A | A |
| Example 2 | P-2 | A | A |
| Example 3 | P-3 | A | A |
| Example 4 | P-4 | A | A |
| Example 5 | P-5 | A | A |
| Example 6 | P-6 | A | A |
| Example 7 | P-7 | A | A |
| Example 8 | P-8 | A | A |
| Example 9 | P-9 | A | A |
| Example 10 | P-10 | A | A |
| Example 11 | P-11 | A | A |
| Example 12 | P-12 | A | A |
| Example 13 | P-13 | A | A |
| Example 16 | P-16 | A | A |
| Example 17 | P-17 | A | A |
| Example 18 | P-18 | A | A |
| Example 19 | P-19 | A | A |
| Example 20 | P-20 | A | A |
| Example 22 | P-22 | A | A |
| Example 23 | P-23 | A | A |
| Comparative Example 1 | CP-1 | A | X |
| Comparative Example 2 | CP-2 | A | A |
| Comparative Example 3 | CP-3 | A | A |

Resistance to Acid:

A (Very good): unevenness is not observed, or the proportion thereof is less than 1% of the total area even in the case of being observed.

B (Good): at least one of peeling and streaking is observed, but the proportion thereof is 1% or more and less than 10% of the total area.

X (Bad): The film is dissolved.

Resistance to Alkali:

A (Very good): unevenness is not observed, or the proportion thereof is less than 1% of the total area even in the case of being observed.

B (Good): at least one of peeling and streaking is observed, but the proportion thereof is 1% or more and less than 10% of the total area.

X (Bad): The film is dissolved.

As shown in Tables 1 and 2, in the cured films obtained from the solution compositions P-1 to 13, P-16 to 20, P-22, and P-23, respectively obtained in Examples 1 to 13, 16 to 20, 22, and 23, which are the embodiments of the resin compositions of the present invention, the “resistance to NMP and PGMEA” was “B” or “A”. On the other hand, in all of the cured films of Comparative Examples 1, 2, and 3, the resistance to NMP and PGMEA was “X”. From these results, it has been found that the cured films of Examples have significantly improved organic solvent resistance as compared with the cured films of Comparative Examples 1, 2, and 3 which are in the scope of Patent Documents 4 and 5.

In addition, in the cured films obtained from the solution compositions P-1 to 13, P-16 to 20, P-22, and P-23, respectively obtained in Examples 1 to 13, 16 to 20, 22, and 23, Td₅ was observed in the range of 370° C. to 435° C., the transmittance was more than 95% in all cases, and the resistance to acid and alkali was “A” in all cases. On the other hand, in the cured films of Comparative Examples 1, 2, and 3, Td₅ was respectively observed at 360° C., 400° C., and 430° C., the transmittance was more than 95% in all cases, and the resistance to acid and alkali was “A” or “X”. That is, it can be seen that regarding the performances of heat stability (Td₅), transparency, acid resistance, and alkali resistance, the resin compositions of Examples have performances equal to or higher than those of the resin compositions of Comparative Examples 1 to 3.

From the above, it has been found that the cured films of the resin compositions of Examples have physical properties equal to or excellent than those of the cured films of Comparative Examples 1, 2, and 3 in terms of thermal decomposition temperature, that is, heat resistance, transparency, acid resistance, and alkali resistance, and have significantly excellent organic solvent resistance as compared with the cured films of Comparative Examples 1, 2, and 3, and as a result, an excellent cured film in which each of the performances is well balanced can be obtained.

[Evaluation of Adhesion]

Adhesion was evaluated for the cured films obtained from the above solution compositions P-2 to P-4, P-7 to P-9, P-13, P-16 to P-20, P-22, and P-23 according to JIS K 5400 (cross-cut adhesion test). Specifically, 100 lattices of 1 mm square were formed on the cured film with a cutter knife and then kept in an environment of 85° C. and 85% relative humidity for 3 days. Cellophane tape was attached to the lattice portion of the obtained cured film and then peeled off for visual confirmation. No peeling was observed in all the cured films, and it has been found that the cured films exhibit sufficient adhesion.

[Patterning Evaluation Using Naphthoquinone Diazide Compound]

0.5 g of a naphthoquinone diazide compound TKF-528 (manufactured by SANBO CHEMICAL Ind. Co., Ltd.) was added, as a photosensitizer, to 10 g of each of the solution compositions P-1 to P-4, P-7 to P-9, P-11, P-13, P-17 to P-20, P-22, and P-23, which were respectively obtained in Examples 1 to 4, 7 to 9, 11, 13, 17 to 20, 22, and 23, and stirred thereby respectively obtaining homogeneous photosensitive solution compositions PP-1 to PP-4, PP-7 to PP-9, PP-11, PP-13, PP-17 to PP-20, PP-22, and PP-23.

Thereafter, a silicon wafer was spin-coated (1 minute at 1500 rpm) with the obtained photosensitive solution composition and then heat-treated at 100° C. for 1 minute to obtain a photosensitive resin film. Next, the photosensitive resin film was subjected to an exposure treatment over a photomask under the condition of 150 mJ/cm² with an exposure apparatus, then immersed in a 2.38% by weight tetramethylammonium hydroxide aqueous solution for 1 minute, and subsequently immersed in water 30 seconds and washed. Thereafter, the entire surface was exposed with an exposure apparatus under the condition of 300 mJ/cm², then heat-treated at 110° C. for 1.5 minutes, and subsequently heat-treated at 230° C. for 1 hour to obtain a patterned cured film in which a positive type pattern was formed. The patterned cured film had a line-and-space pattern resolution of 10 to 20 μm and a film thickness of 1 to 2 μm.

[Patterning Evaluation Using Photoacid Generator]

0.03 g of Irgacure 121 (manufactured by BASF USA Ltd.) which is a photoacid generator was added to 10 g of each of the solution compositions P-14, P-15, and P-21, which were respectively obtained in Examples 14, 15, and 21, and stirred to respectively obtain homogeneous photosensitive solution compositions PP-14, PP-15, and PP-21.

Thereafter, a silicon wafer was spin-coated (1 minute at 1500 rpm) with the obtained photosensitive solution composition and then heat-treated at 100° C. for 1 minute to obtain a photosensitive resin film. Next, the photosensitive resin film was subjected to an exposure treatment over a photomask under the condition of 105 mJ/cm² with an exposure apparatus, subjected again to the heating treatment at 100° C., then immersed in a 2.38% by weight tetramethylammonium hydroxide aqueous solution for 1 minute, and subsequently immersed in water 30 seconds and washed. Thereafter, the heating treatment at 110° C. for 1.5 minutes and the subsequent heating treatment at 230° C. for 1 hour were performed to obtain a patterned cured film in which a positive type pattern was formed. The patterned cured film had a line-and-space pattern resolution of 10 to 20 μm and a film thickness of 1 to 2 μm.

As described above, it has been found that the cured films obtained from the resin compositions of Examples have high thermal decomposition temperature, that is, high heat resistance, excellent transparency, excellent resistance to organic solvents for general use such as NMP and PGMEA, acids, and alkalis, and adhesion to silicon is also good. In addition, it has been found that a cured film in which a positive type pattern is formed can be obtained from a photosensitive resin composition (this is also the embodiment of the present invention) obtained by adding a photosensitizer such as a naphthoquinone diazide compound or an acid generator to the composition.

### Example 24

In Example 24, unlike Examples 14, 15, and 21, a polysiloxane compound was produced using an alkoxysilane (a monomer) into which an acid-labile group was introduced in advance (in Examples 14, 15, and 21, first, a polysiloxane compound was obtained, and then an acid-labile group was introduced). Then, a solution composition was produced using the produced polysiloxane compound. The specific description thereof is as follows.

First, as an alkoxysilane (a monomer) into which an acid-labile group was introduced in advance, a compound (also described as HFA-Si-MOM) represented by the following chemical formula was produced according to the method described below (“Production of monomer in which acid-labile group is introduced”).

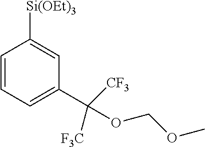

(Production of Monomer in which Acid-Labile Group is Introduced)

The compound (150 g, 0.37 mmol) represented by Formula (ME-1) obtained in Synthesis Example 4 was dropwise added to a solution of a mixture of THF (150 g) and NaH (16.2 g, 0.41 mol) in a three-necked flask placed in an ice bath, and then chloromethyl methyl ether (32.6 g, 0.38 mol) was dropwise added thereto. Thereafter, the mixture was stirred at room temperature for 20 hours.

After the above stirring was completed, the reaction solution was concentrated with an evaporator. 300 g of toluene and 150 g of water were added to the concentrated reaction solution and stirred. After stirring, the mixture was allowed to stand for a while to separate the mixture into two layers, and then the lower aqueous layer was removed. 150 g of water was further added to the obtained upper organic layer, and the same operation above was repeated. The finally obtained upper organic layer was concentrated with an evaporator to obtain 180 g of a crude product.

The obtained crude product was simply distilled (vacuum degree: 2.5 kPa, bath temperature: 200° C. to 220° C., top temperature: 170° C.) to obtain 145 g of HFA-Si-MOM.

Next, a solution composition (P-24) was produced as follows (“Polymerization reaction and production of solution composition”).

(Polymerization Reaction and Production of Solution Composition)

HFA-Si-MOM (3 g, 6.7 mmol) produced as described above, phenyltriethoxysilane (12.8 g, 53 mmol), KBM-303 (1.6 g, 7 mmol, also used in other Examples), water (3.8 g, 210 mmol), EtOH (10 g), 0.24 g of a 25% by mass TMAH aqueous solution (0.06 g, 0.7 mmol in terms of TMAH) were added in a 50 mL flask, and the resultant mixture was stirred at 60° C. for 4 hours.

Toluene (5 g) was added to the reaction solution, and the mixture was refluxed at 105° C. for 20 hours with a Dean-Stark apparatus to distill off water and EtOH. Washing with water was performed 3 times (2 g of water was used for each time), and then the organic layer was concentrated with an evaporator (30 hPa, 60° C., 30 min) to obtain 10 g of a polysiloxane compound.

The polysiloxane compound was dissolved in 20 g of propylene glycol monomethyl ether acetate to obtain a solution composition (P-24) having a solid content concentration of 33% by mass. The Mw of the polysiloxane compound measured by GPC was 1,700.

### Example 25

A solution composition (P-25) was obtained in the same manner as in Example 24, except that the molar ratio of the raw material (the monomer) charged in the polymerization reaction was changed as shown in the table below.

### Example 26

A solution composition (P-26) was obtained in the same manner as in Example 24, except that the molar ratio of the raw material (the monomer) charged in the polymerization reaction was changed as shown in the table below. [Example 27]

A solution composition (P-27) was obtained in the same manner as in Example 24, except that the kind and the molar ratio of the raw material (the monomer) charged in the polymerization reaction was changed as shown in the table below.

### Example 28

A solution composition (P-28) was obtained in the same manner as in Example 24, except that the kind and the molar ratio of the raw material (the monomer) charged in the polymerization reaction was changed as shown in the table below.

Information on Examples 24 to 28 is summarized in the table below. In the table below, Ph-Si is phenyltriethoxysilane, KBM-5103 is 3-acryloxypropyltrimethoxysilane manufactured by Shin-Etsu Chemical Co., Ltd., and ethyl polysilicate is Silicate 40 (trade name) manufactured by Tama Chemicals Co., Ltd. Other notations are as described above.

[Table 3]

TABLE 3

| | Composition ratio (molar ratio) | | |
|---|---|---|---|
| | of charging in production | Polymer- | Mw of |
| Solution | (polymerization reaction) of | ization | polysiloxane |
| composition | polysiloxane compound | catalyst | compound |
| P-24 | HFA-Si-MOM/Ph-Si/KBM-303 | TMAH | 1,700 |
| | (1/8/1) | | |
| P-25 | HFA-Si-MOM/Ph-Si/KBM-303 | TMAH | 2,000 |
| | (3/5/2) | | |
| P-26 | HFA-Si-MOM/Ph-Si/KBM-303 | TMAH | 1,900 |
| | (5/2/3) | | |
| P-27 | HFA-Si-MOM/Ph-Si/KBM-5103 | TMAH | 1,800 |
| | (1/1/1) | | |
| P-28 | HFA-Si-MOM/Ethyl polysilicate | TMAH | 1,700 |
| | (8/2) | | |

[Transparency Evaluation]

A 4-inch glass substrate was spin-coated with each of the solution compositions P-24 to P-28 at a rotation speed of 500 rpm. Thereafter, the coated substrate was dried on a hot plate at 100° C. for 3 minutes. Thereafter, the substrate was baked at 230° C. for 1 hour. In this manner, a cured film of a polysiloxane having a film thickness of 1 to 2 μm was obtained on the glass substrate. Then, the transmission spectrum of the cured film was measured.

All the transmittances of the cured films obtained from the solution compositions P-24 to P-28 at a wavelength of 400 nm in terms of a film thickness of 2 μm were more than 90%. In addition, the transmittance of the cured film obtained from the solution compositions P-28 at a wavelength of 350 nm in terms of a film thickness of 2 μm was more than 90%.

Due to the good light-transmitting property at the wavelength of 350 to 400 nm shown here, the polysiloxane compound produced by using the alkoxysilane (the monomer) in which an acid-labile group is introduced in advance is preferably applicable to coating materials for a photosensitive composition, an organic EL, a liquid crystal display, and a CMOS image sensor.

[Patterning Evaluation]

0.04 g of a photoacid generator CP-100TF (manufactured by San-Apro Ltd.) was added to 3 g of each of the solution compositions P-24 to P-28 and stirred to produce homogeneous photosensitive solution compositions PP-24 to PP-28.

A silicon wafer having a diameter of 4 inches and a thickness of 525 μm, manufactured by SUMCO Corporation, was spin-coated with the obtained photosensitive solution composition at a rotation speed of 500 rpm. Thereafter, the coated silicon wafer was heat-treated on a hot plate at 100° C. for 3 minutes to obtain a photosensitive resin film having a film thickness of 1 to 2 μm.

The obtained photosensitive resin film was irradiated with light of 108 mJ/cm² from a high-pressure mercury lamp through a photomask using an exposure apparatus. Thereafter, the irradiated photosensitive resin film was heat-treated on a hot plate at 150° C. for 1 minute. Thereafter, the heat-treated photosensitive resin film was immersed in a 2.38% by mass tetramethylammonium hydroxide aqueous solution for 1 minute for development, and then immersed in water for 30 seconds for washing. After washing, the photosensitive resin film was baked in an oven at 230° C. for 1 hour in the air. As a result, a patterned cured film in which a positive pattern was formed was obtained.

A line-and-space resolution of 10 to 20 μm was obtained regarding all of the photosensitive solution compositions PP-24 to PP-28. That is, a photosensitive resin composition having good performance could be obtained by synthesizing a polysiloxane compound using an alkoxysilane (a monomer) in which an acid-labile group was introduced in advance and producing a photosensitive resin composition using the synthesized polysiloxane compound.

### Example 29

In Example 29, the usefulness of the resin composition containing the component (A1), the component (A2), and the component (B) is shown with some embodiments.

First, the following polymers were prepared.

(Polymer Corresponding to Component (A1))
P-HFA-Si: A compound obtained by singly condensation-polymerizing a compound represented by Formula (ME-1) which is obtained in Synthesis Example 4, under the same acetic acid catalyst conditions as in Example 1, Mw=2,100.
P-HFA-Si-MOM: A compound obtained by singly condensation-polymerizing HFA-Si-MOM (an acid labile group-containing monomer) synthesized in Example 24, Mw=2,100.
P-HFA-Si-BOC: A compound obtained by singly condensation-polymerizing HFA-Si-BOC (an acid labile group-containing monomer) synthesized as follows, Mw=1,800.

(Synthesis of HFA-Si-BOC)

THF (10 g), NaH (1.2 g, 0.03 mol), and the compound (10 g, 0.025 mol) represented by Formula (ME-1) described in Synthesis Example 4 were added in a three-necked flask placed in an ice bath and stirred for 30 minutes. Thereafter, di-tert-butyl dicarbonate (5.2 g, 0.027 mol) and tetrabutylammonium iodide (0.3 g, 0.001 mol) were added in the flask, and the resultant mixture was stirred at room temperature for 18 hours.

Diisopropyl ether (20 g) and water (10 g) were added to the obtained reaction product, stirred, and then allowed to stand for a while. After allowing the mixture to stand and to be separated into two layers, the lower aqueous layer was removed. The obtained upper organic layer was dried with magnesium sulfate and then concentrated with an evaporator to obtain 10 g of HFA-Si-BOC (yield: 83%, GC purity: 95%).

For reference, the chemical formula of HFA-Si-BOC is shown below.

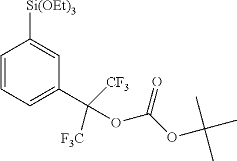

(Polymer Corresponding to Component (A2))
P-KBM-303: A compound obtained by singly condensation-polymerizing 2-(3,4-epoxycyclohexylethyltrimethoxysilane) (KBM-303 manufactured by Shin-Etsu Chemical Co., Ltd.), Mw=1,900
P-KBM-5103: A compound obtained by singly condensation-polymerizing 3-acryloxypropyltrimethoxysilane (KBM-5103 manufactured by Shin-Etsu Chemical Co., Ltd.), Mw=2,200
P-KBM-303/ethyl polysilicate (8/2: molar ratio): A compound obtained by copolymerizing 2-(3,4-epoxycyclohexylethyltrimethoxysilane) (KBM-303 manufactured by Shin-Etsu Chemical Co., Ltd.) and ethyl polysilicate (Silicate 40, manufactured by Tama Chemicals Co., Ltd.), Mw=2,000
P-Ph-Si: A compound obtained by singly condensation-polymerizing phenyltriethoxysilane, Mw=2,500

Solution compositions P-29 to P-33 having a solid content concentration mass of 25% were produced using a polymer corresponding to the component (A1), a polymer corresponding to the component (A2), and propylene glycol monomethyl ether acetate (PGMEA) as the solvent.

In the table below, the composition ratio (the mixing ratio) of the polymer is shown as a value converted into the number of moles used (the number of moles of charging) of the monomer used in synthesizing the polymer.

TABLE 4

| Solution | Composition ratio (molar ratio of charging in terms |
|---|---|
| composition | of monomer) |
| P-29 | P-HFA-Si + P-Ph-Si + P-KBM-303 (1/8/1) |
| P-30 | P-HFA-Si + P-Ph-Si + P-KBM-5103 (2/7/2) |
| P-31 | P-HFA-Si + P-Ph-Si + P-KBM-303/Ethyl silicate (3/4/3) |
| P-32 | P-HFA-Si-MOM + P-Ph-Si + P-KBM-303 (3/6/1) |
| P-33 | P-HFA-Si-BOC + P-Ph-Si + P-KBM-303 (2/6/2) |

The solvent resistance of the solution compositions P-29 to P-31 was evaluated in the same manner as in Example 1 (the solution composition P-1). The evaluation results are shown in the table below.

TABLE 5

| Solution | | | | |
|---|---|---|---|---|
| composition | PGMEA | NMP | Acid | Alkali |
| P-29 | A | A | A | A |
| P-30 | B | B | A | A |
| P-31 | A | A | A | A |

As shown in the above table, it has been found that in a case where a resin composition containing the component (A1), the component (A2), and the component (B) are used, an excellent cured film can be also obtained as in the case where the resin composition containing the component (A) and the component (B).

In addition, 0.12 g of a photoacid generator CPI-110TF manufactured by San-Apro Ltd. was added to 10 g of each of the solution compositions P-32 and P-33, and the resultant mixture was homogeneously mixed to obtain photosensitive solution compositions PP-32 and PP-33. Patterning evaluation was carried out in the same manner as in the above-described photosensitive solution compositions PP-14, PP-15, and PP-21. As a result, it was possible to obtain a line-and-space pattern resolution having a film thickness of 1 to 2 μm and a line width of 10 to 20 μm. That is, in a case where a resin composition containing the component (A1), the component (A2), and the component (B) were used, a positive type patterned cured film could be also obtained as in the case where the resin composition containing the component (A) and the component (B).

This application claims priority based on Japanese Patent Application No. 2018-204332 filed on Oct. 30, 2018, and all contents of the disclosure are incorporated herein.

The resin composition obtained by the present invention can be made into a photosensitive resin composition having patterning performance by alkaline development by adding a photosensitizer to the composition. Since the cured films obtained from both of the compositions are excellent in heat resistance, transparency, chemical liquid resistance, and adhesion, the cured films can be used for a semiconductor protective film, a protective film for an organic EL or a liquid crystal display, a coating material for an image sensor, a flattening material and a microlens material, an insulating protective film material for a touch panel, a flattening material for a liquid crystal display TFT, a core or clad forming material for an optical waveguide, a resist for an electron beam, an intermediate film for a multilayer resist, an underlayer film, an antireflection film, and the like. Among the intended uses described above, in a case of being used for optical system members such as a display and an image sensor, fine particles such as polytetrafluoroethylene, silica, titanium oxide, zirconium oxide, and magnesium fluoride are mixed and used in any ratio for the purpose of adjusting the refractive index.

1. A resin composition comprising:
a component (A) and a component (B),
the component (A): a polysiloxane compound containing a constitutional unit represented by Formula (1) and at least one of a constitutional unit of Formula (2) and a constitutional unit of Formula (3), and
[(R^{x})_{b}R¹ₘSiO_{n/2}] (1)
[in the formula, R^{x} is a monovalent group represented by Formula (1a) 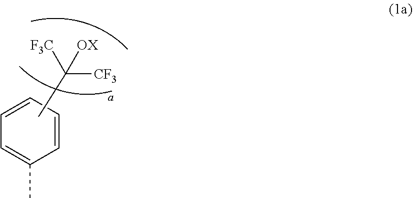
(X is a hydrogen atom or an acid-labile group, a is an integer of 1 to 5, and a broken line represents a bond), R¹ is a hydrogen atom, an alkyl group having 1 to 3 carbon atoms, a phenyl group, a hydroxy group, an alkoxy group having 1 to 3 carbon atoms, or a fluoroalkyl group having 1 to 3 carbon atoms, b is an integer of 1 to 3, m is an integer of 0 to 2, and n is an integer of 1 to 3, where b+m+n is 4, and in a case where a plurality of R^{x}'s and R¹'s are present, R^{x}'s and R¹'s each may be independently the aforementioned group as a substituent],
[(R^{y})_{c}R²ₚSiO_{q/2}] (2)
[in the formula, R^{y} is a monovalent organic group having 1 to 30 carbon atoms, which contains any one of an epoxy group, an oxetane group, an acryloyl group, and a methacryloyl group, R² is a hydrogen atom, an alkyl group having 1 to 3 carbon atoms, a phenyl group, a hydroxy group, an alkoxy group having 1 to 3 carbon atoms, or a fluoroalkyl group having 1 to 3 carbon atoms, c is an integer of 1 to 3, p is an integer of 0 to 2, and q is an integer of 1 to 3, where c+p+q is 4, and in a case where a plurality of R^{y} 's and R²'s are present, R^{y} 's and R²'s each may be independently the aforementioned group as a substituent],
[SiO_{4/2}] (3)
the component (B): a solvent.

2. The resin composition according to claim 1, wherein the group represented by Formula (1a) is any one of groups represented by Formulae (1aa) to (1ad), 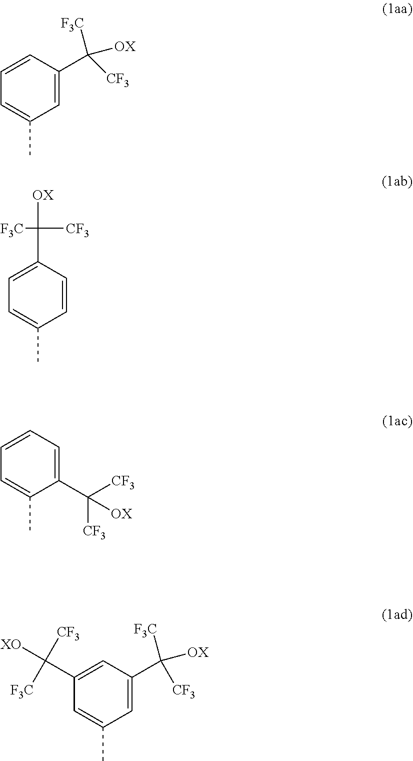
(in the formulae, broken lines represent a bond).

3. The resin composition according to claim 1, wherein the monovalent organic group R^{y} is a group represented by Formula (2a), (2b), (2c), (3a), or (4a), 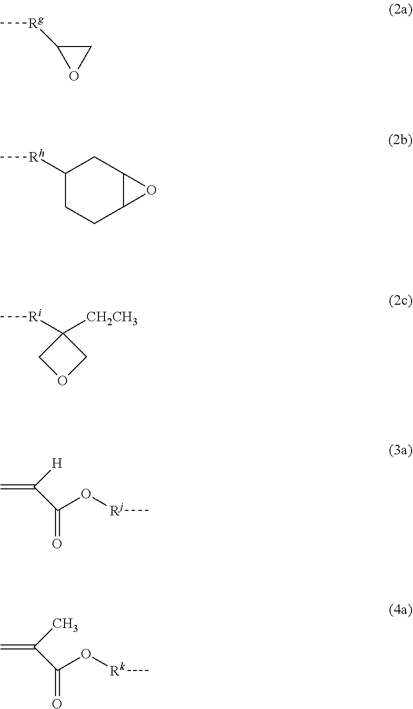
(in the formulae, R^{g}, R^{h}, Rⁱ, R^{j}, and R^{k} each independently represent a linking group or a divalent organic group, and broken lines represent a bond).

4. The resin composition according to claim 1, wherein the solvent is a solvent containing at least one compound selected from the group consisting of propylene glycol monomethyl ether acetate, propylene glycol monomethyl ether, cyclohexanone, ethyl lactate, γ-butyrolactone, diacetone alcohol, diglyme, methyl isobutyl ketone, 3-methoxybutyl acetate, 2-heptanone, N,N-dimethylformamide, N,N-dimethylacetamide, N-methylpyrrolidone, glycols, glycol ethers, and glycol ether esters.

5. A resin composition comprising:
a component (A1), a component (A2), and a component (B),
the component (A1): a polymer containing a constitutional unit represented by Formula (1), but containing none of a constitutional unit of Formula (2) and a constitutional unit of Formula (3), and
the component (A2): a polymer containing at least one of a constitutional unit of Formula (2) and a constitutional unit of Formula (3), but not containing a constitutional unit represented by Formula (1),
[(R^{x})_{b}R¹ₘSiO_{n/2}] (1)
[in the formula, R^{x} is a monovalent group represented by Formula (1a), 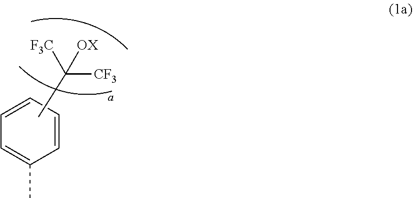
(X is a hydrogen atom or an acid-labile group, a is an integer of 1 to 5, and a broken line represents a bond), R′ is a hydrogen atom, an alkyl group having 1 to 3 carbon atoms, a phenyl group, a hydroxy group, an alkoxy group having 1 to 3 carbon atoms, or a fluoroalkyl group having 1 to 3 carbon atoms, b is an integer of 1 to 3, m is an integer of 0 to 2, and n is an integer of 1 to 3, where b+m+n=4, and in a case where a plurality of R^{x}'s and R¹'s are present, R^{x}'s and R¹'s each may be independently the aforementioned group as a substituent],
[(R^{y})_{c}R²ₚSiO_{q/2}] (2)
[in the formula, R^{y} is a monovalent organic group having 1 to 30 carbon atoms, which contains any one of an epoxy group, an oxetane group, an acryloyl group, and a methacryloyl group, R² is a hydrogen atom, an alkyl group having 1 to 3 carbon atoms, a phenyl group, a hydroxy group, an alkoxy group having 1 to 3 carbon atoms, or a fluoroalkyl group having 1 to 3 carbon atoms, c is an integer of 1 to 3, p is an integer of 0 to 2, and q is an integer of 1 to 3, where c+p+q is 4, and in a case where a plurality of R^{y} 's and R²'s are present, R^{y} 's and R²'s each may be independently the aforementioned group as a substituent],
[SiO_{4/2}] (3)
the component (B): a solvent.

6. A photosensitive resin composition comprising:
the resin composition according to claim 1 and a photosensitizer as a component (C), which is selected from a quinone diazide compound, a photoacid generator, and photoradical generator.

7. A cured film of the resin composition according to claim 1.

8. A method for manufacturing a cured film, comprising applying the resin composition according to claim 1 onto a substrate and then performing heating at a temperature of 100° C. to 350° C.

9. A patterned cured film of the photosensitive resin composition according to claim 6.

10. A method for manufacturing a patterned cured film, comprising:
applying the photosensitive resin composition according to claim 6 onto a substrate and performing drying to form a photosensitive resin film,
exposing the photosensitive resin film,
developing the exposed photosensitive resin film to form a patterned resin film, and
heating the patterned resin film to cure the patterned resin film such that the patterned resin film is converted into a patterned cured film.

11. The method for manufacturing the patterned cured film according to claim 10, wherein a wavelength of light that is used for exposing the photosensitive resin film is 100 to 600 nm.

12. A method for producing the resin composition according to claim 1, comprising:
converting a hydrogen atom of a hydroxy group of an alkoxysilane represented by Formula (7) or Formula (7-1) into an acid-labile group to obtain an acid labile group-containing alkoxysilane, subsequently hydrolyzing and polycondensing the acid labile group-containing alkoxysilane to obtain a polysiloxane compound, and using the obtained polysiloxane compound as the polysiloxane compound of the component (A) in a case of producing the resin composition, 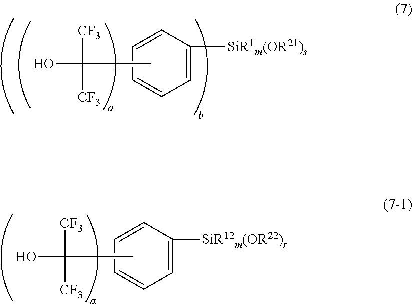
[in Formula (7), R¹s are each independently a hydrogen atom, an alkyl group having 1 to 3 carbon atoms, a phenyl group, a hydroxy group, an alkoxy group having 1 to 3 carbon atoms, or a fluoroalkyl group having 1 to 3 carbon atoms, R²¹'s are each independently a linear alkyl group having 1 to 4 carbon atoms or a branched alkyl group having 3 or 4 carbon atoms, all or a part of hydrogen atoms in the alkyl group may be substituted with fluorine atoms, a is an integer of 1 to 5, b is an integer of 1 to 3, m is an integer of 0 to 2, and s is an integer of 1 to 3, where b+m+s is 4, and in Formula (7-1), R¹²'s are each independently a hydrogen atom, an alkyl group having 1 to 3 carbon atoms, a phenyl group, a hydroxy group, an alkoxy group having 1 to 3 carbon atoms, or a fluoroalkyl group having 1 to 3 carbon atoms, R²²'s are each independently a linear alkyl group having 1 to 4 carbon atoms or a branched alkyl group having 3 or 4 carbon atoms, all or a part of hydrogen atoms in the alkyl group may be substituted with fluorine atoms, a is an integer of 1 to 5, m is an integer of 0 to 2, and r is an integer of 1 to 3, where m+r is 3].

13. A method for producing the resin composition according to claim 1, comprising:
hydrolyzing and polycondensing an alkoxysilane represented by Formula (7) or Formula (7-1) to obtain a polymer, subsequently converting a hydrogen atom of a hydroxy group of the polymer into an acid-labile group to obtain a polysiloxane compound, and using the obtained polysiloxane compound as the polysiloxane compound of the component (A) in a case of producing the resin composition, 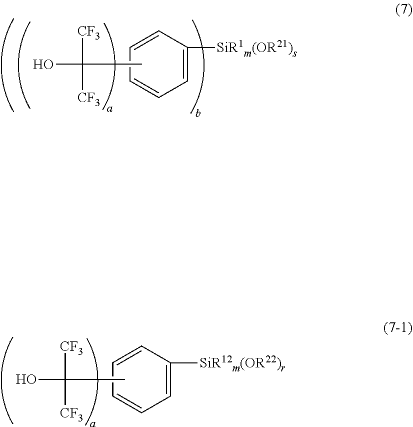
[in Formula (7), R¹'s are each independently a hydrogen atom, an alkyl group having 1 to 3 carbon atoms, a phenyl group, a hydroxy group, an alkoxy group having 1 to 3 carbon atoms, or a fluoroalkyl group having 1 to 3 carbon atoms, R²¹'s are each independently a linear alkyl group having 1 to 4 carbon atoms or a branched alkyl group having 3 or 4 carbon atoms, all or a part of hydrogen atoms in the alkyl group may be substituted with fluorine atoms, a is an integer of 1 to 5, b is an integer of 1 to 3, m is an integer of 0 to 2, and s is an integer of 1 to 3, where b+m+s is 4, and in Formula (7-1), R¹²s are each independently a hydrogen atom, an alkyl group having 1 to 3 carbon atoms, a phenyl group, a hydroxy group, an alkoxy group having 1 to 3 carbon atoms, or a fluoroalkyl group having 1 to 3 carbon atoms, R²²'s are each independently a linear alkyl group having 1 to 4 carbon atoms or a branched alkyl group having 3 or 4 carbon atoms, all or a part of hydrogen atoms in the alkyl group may be substituted with fluorine atoms, a is an integer of 1 to 5, m is an integer of 0 to 2, and r is an integer of 1 to 3, where m+r is 3].

14. A method for producing the resin composition according to claim 5, comprising:
converting a hydrogen atom of a hydroxy group of an alkoxysilane represented by Formula (7) or Formula (7-1) into an acid-labile group to obtain an acid labile group-containing alkoxysilane, subsequently hydrolyzing and polycondensing the acid labile group-containing alkoxysilane to obtain a polymer, and using the obtained polymer as the polymer of the component (A1) in a case of producing the resin composition, 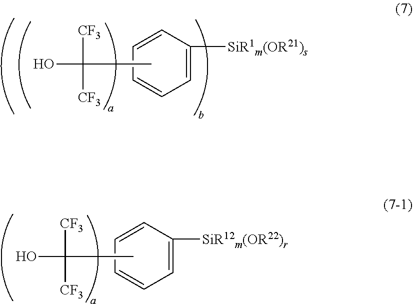
[in Formula (7), R¹'s are each independently a hydrogen atom, an alkyl group having 1 to 3 carbon atoms, a phenyl group, a hydroxy group, an alkoxy group having 1 to 3 carbon atoms, or a fluoroalkyl group having 1 to 3 carbon atoms, R²¹'s are each independently a linear alkyl group having 1 to 4 carbon atoms or a branched alkyl group having 3 or 4 carbon atoms, all or a part of hydrogen atoms in the alkyl group may be substituted with fluorine atoms, a is an integer of 1 to 5, b is an integer of 1 to 3, m is an integer of 0 to 2, and s is an integer of 1 to 3, where b+m+s is 4, and in Formula (7-1), R¹²'s are each independently a hydrogen atom, an alkyl group having 1 to 3 carbon atoms, a phenyl group, a hydroxy group, an alkoxy group having 1 to 3 carbon atoms, or a fluoroalkyl group having 1 to 3 carbon atoms, R²²'s are each independently a linear alkyl group having 1 to 4 carbon atoms or a branched alkyl group having 3 or 4 carbon atoms, all or a part of hydrogen atoms in the alkyl group may be substituted with fluorine atoms, a is an integer of 1 to 5, m is an integer of 0 to 2, and r is an integer of 1 to 3, where m+r is 3].

15. A method for producing the resin composition according to claim 5, comprising:
hydrolyzing and polycondensing an alkoxysilane represented by Formula (7) or Formula (7-1) to obtain a polymer, subsequently converting a hydrogen atom of a hydroxy group of the polymer into an acid-labile group to obtain a polymer, and using the obtained polymer as the polymer of the component (A1) in a case of producing the resin composition, 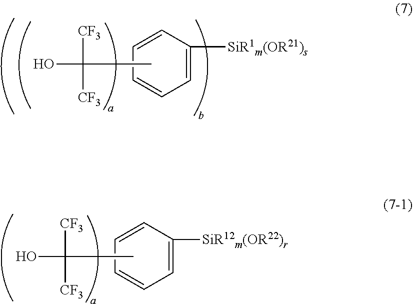
[in Formula (7), R¹'s are each independently a hydrogen atom, an alkyl group having 1 to 3 carbon atoms, a phenyl group, a hydroxy group, an alkoxy group having 1 to 3 carbon atoms, or a fluoroalkyl group having 1 to 3 carbon atoms, R²¹'s are each independently a linear alkyl group having 1 to 4 carbon atoms or a branched alkyl group having 3 or 4 carbon atoms, all or a part of hydrogen atoms in the alkyl group may be substituted with fluorine atoms, a is an integer of 1 to 5, b is an integer of 1 to 3, m is an integer of 0 to 2, and s is an integer of 1 to 3, where b+m+s is 4, and in Formula (7-1), R¹²'s are each independently a hydrogen atom, an alkyl group having 1 to 3 carbon atoms, a phenyl group, a hydroxy group, an alkoxy group having 1 to 3 carbon atoms, or a fluoroalkyl group having 1 to 3 carbon atoms, R²²'s are each independently a linear alkyl group having 1 to 4 carbon atoms or a branched alkyl group having 3 or 4 carbon atoms, all or a part of hydrogen atoms in the alkyl group may be substituted with fluorine atoms, a is an integer of 1 to 5, m is an integer of 0 to 2, and r is an integer of 1 to 3, where m+r is 3].

16. A photosensitive resin composition comprising:
the resin composition according to claim 5 and a photosensitizer as a component (C), which is selected from a quinone diazide compound, a photoacid generator, and photoradical generator.

17. A cured film of the resin composition according to claim 5.

18. A method for manufacturing a cured film, comprising applying the resin composition according to claim 5 onto a substrate and then performing heating at a temperature of 100° C. to 350° C.
